(19) United States
(12) Patent Application Publication
(10) Pub. No.: US 2025/0385750 A1
(43) Pub. Date: Dec. 18, 2025

(54) PUNCTURING SCHEME FOR SPINAL CODES

(71) Applicant: QUALCOMM Incorporated, San Diego, CA (US)

(72) Inventors: Peer BERGER, Hod Hasharon (IL); Matan GUETTA, Kiryat Ono (IL); Amit BAR-OR TILLINGER, Tel-Aviv (IL)

(21) Appl. No.: 18/741,617

(22) Filed: Jun. 12, 2024

(51) Int. Cl. H04L 1/00

(52) U.S. Cl. CPC H04L 1/0013; H04L 1/0036

(57) ABSTRACT

Methods, systems, and devices for wireless communications are described. A user equipment (UE), may receive, from a network entity, an indication of a puncturing scheme for a spinal coding scheme based on a capability of the UE, where the puncturing scheme indicates a puncturing distribution for one or more symbols of one or more spines of the spinal coding scheme. The UE may receive a message encoded by the network entity according to the spinal coding scheme associated with the puncturing scheme. The UE may decode the message encoded according to the spinal coding scheme to obtain one or more message segments corresponding to the one or more symbols and to the one or more spines based on the puncturing distribution of the puncturing scheme.

### FIELD OF TECHNOLOGY

The following relates to wireless communications, including improved puncturing scheme for spinal codes.

### BACKGROUND

Wireless communications systems are widely deployed to provide various types of communication content such as voice, video, packet data, messaging, broadcast, and so on. These systems may be capable of supporting communication with multiple users by sharing the available system resources (e.g., time, frequency, and power). Examples of such multiple-access systems include fourth generation (4G) systems such as Long Term Evolution (LTE) systems, LTE-Advanced (LTE-A) systems, or LTE-A Pro systems, and fifth generation (5G) systems which may be referred to as New Radio (NR) systems. These systems may employ technologies such as code division multiple access (CDMA), time division multiple access (TDMA), frequency division multiple access (FDMA), orthogonal FDMA (OFDMA), or discrete Fourier transform spread orthogonal frequency division multiplexing (DFT-S-OFDM). A wireless multiple-access communications system may include one or more base stations, each supporting wireless communication for communication devices, which may be known as user equipment (UE).

### SUMMARY

The systems, methods, and devices of this disclosure each have several innovative aspects, no single one of which is solely responsible for the desirable attributes disclosed herein.

A method for wireless communications by a user equipment (UE) is described. The method may include receiving, from a network entity, an indication of a puncturing scheme for a spinal coding scheme based on a capability of the UE, where the puncturing scheme indicates a puncturing distribution for one or more symbols of one or more spines of the spinal coding scheme, receiving, from the network entity, a message encoded according to the spinal coding scheme associated with the puncturing scheme, and decoding the message encoded according to the spinal coding scheme to obtain one or more message segments corresponding to the one or more symbols and to the one or more spines based on the puncturing distribution of the puncturing scheme.

A UE for wireless communications is described. The UE may include one or more memories storing processor executable code, and one or more processors coupled with the one or more memories. The one or more processors may individually or collectively be operable to execute the code to cause the UE to receive, from a network entity, an indication of a puncturing scheme for a spinal coding scheme based on a capability of the UE, where the puncturing scheme indicates a puncturing distribution for one or more symbols of one or more spines of the spinal coding scheme, receive, from the network entity, a message encoded according to the spinal coding scheme associated with the puncturing scheme, and decode the message encoded according to the spinal coding scheme to obtain one or more message segments corresponding to the one or more symbols and to the one or more spines based on the puncturing distribution of the puncturing scheme.

Another UE for wireless communications is described. The UE may include means for receiving, from a network entity, an indication of a puncturing scheme for a spinal coding scheme based on a capability of the UE, where the puncturing scheme indicates a puncturing distribution for one or more symbols of one or more spines of the spinal coding scheme, means for receiving, from the network entity, a message encoded according to the spinal coding scheme associated with the puncturing scheme, and means for decoding the message encoded according to the spinal coding scheme to obtain one or more message segments corresponding to the one or more symbols and to the one or more spines based on the puncturing distribution of the puncturing scheme.

A non-transitory computer-readable medium storing code for wireless communications is described. The code may include instructions executable by one or more processors to receive, from a network entity, an indication of a puncturing scheme for a spinal coding scheme based on a capability of the UE, where the puncturing scheme indicates a puncturing distribution for one or more symbols of one or more spines of the spinal coding scheme, receive, from the network entity, a message encoded according to the spinal coding scheme associated with the puncturing scheme, and decode the message encoded according to the spinal coding scheme to obtain one or more message segments corresponding to the one or more symbols and to the one or more spines based on the puncturing distribution of the puncturing scheme.

Some examples of the method, UEs, and non-transitory computer-readable medium described herein may further include operations, features, means, or instructions for transmitting an indication of the capability of the UE to decode the message according to one or more puncturing schemes for the spinal coding scheme, where the indication of the puncturing scheme for the spinal coding scheme may be based on the capability of the UE.

Some examples of the method, UEs, and non-transitory computer-readable medium described herein may further include operations, features, means, or instructions for receiving, based on the capability of the UE, an indication of a second puncturing scheme for the spinal coding scheme different from the puncturing scheme, receiving a second message encoded according to the spinal coding scheme in accordance with the second puncturing scheme, and decoding the second message according to the spinal coding scheme based on a second puncturing distribution of the second puncturing scheme.

In some examples of the method, UEs, and non-transitory computer-readable medium described herein, receiving the indication of the puncturing scheme for the spinal coding scheme may include operations, features, means, or instructions for receiving one of a radio resource control message or a medium access control (MAC) control element (CE) indicating the puncturing scheme.

In some examples of the method, UEs, and non-transitory computer-readable medium described herein, decoding the message may include operations, features, means, or instructions for puncturing the one or more symbols of the one or more spines of the spinal coding scheme based on a uniform puncturing distribution indicated by the puncturing distribution.

In some examples of the method, UEs, and non-transitory computer-readable medium described herein, decoding the message may include operations, features, means, or instructions for puncturing the one or more symbols of the one or more spines of the spinal coding scheme based on a puncturing prioritization associated with the puncturing distribution.

In some examples of the method, UEs, and non-transitory computer-readable medium described herein, the puncturing prioritization includes a prioritization of at least one symbol associated with the beginning of the one or more spines.

In some examples of the method, UEs, and non-transitory computer-readable medium described herein, the puncturing distribution may be based on an average number of consecutive punctured symbols, an average number of spines of the spinal coding scheme, a growth factor associated with one or more puncturing locations, or a combination thereof.

A method for wireless communications by a network entity is described. The method may include outputting, to a UE, an indication of a puncturing scheme for a spinal coding scheme, where the puncturing scheme indicates a puncturing distribution for one or more symbols of one or more spines of the spinal coding scheme, encoding a message according to the spinal coding scheme to indicate one or more message segments corresponding to the one or more symbols and to the one or more spines based on the puncturing distribution of the puncturing scheme, and outputting, to the UE, the message encoded according to the spinal coding scheme associated with the puncturing scheme.

A network entity for wireless communications is described. The network entity may include one or more memories storing processor executable code, and one or more processors coupled with the one or more memories. The one or more processors may individually or collectively be operable to execute the code to cause the network entity to output, to a UE, an indication of a puncturing scheme for a spinal coding scheme, where the puncturing scheme indicates a puncturing distribution for one or more symbols of one or more spines of the spinal coding scheme, encode a message according to the spinal coding scheme to indicate one or more message segments corresponding to the one or more symbols and to the one or more spines based on the puncturing distribution of the puncturing scheme, and output, to the UE, the message encoded according to the spinal coding scheme associated with the puncturing scheme.

Another network entity for wireless communications is described. The network entity may include means for outputting, to a UE, an indication of a puncturing scheme for a spinal coding scheme, where the puncturing scheme indicates a puncturing distribution for one or more symbols of one or more spines of the spinal coding scheme, means for encoding a message according to the spinal coding scheme to indicate one or more message segments corresponding to the one or more symbols and to the one or more spines based on the puncturing distribution of the puncturing scheme, and means for outputting, to the UE, the message encoded according to the spinal coding scheme associated with the puncturing scheme.

A non-transitory computer-readable medium storing code for wireless communications is described. The code may include instructions executable by one or more processors to output, to a UE, an indication of a puncturing scheme for a spinal coding scheme, where the puncturing scheme indicates a puncturing distribution for one or more symbols of one or more spines of the spinal coding scheme, encode a message according to the spinal coding scheme to indicate one or more message segments corresponding to the one or more symbols and to the one or more spines based on the puncturing distribution of the puncturing scheme, and output, to the UE, the message encoded according to the spinal coding scheme associated with the puncturing scheme.

Some examples of the method, network entities, and non-transitory computer-readable medium described herein may further include operations, features, means, or instructions for obtaining an indication of a capability of the UE to decode the message according to one or more puncturing schemes for the spinal coding scheme, where the indication of the puncturing scheme for the spinal coding scheme may be based on the capability of the UE.

Some examples of the method, network entities, and non-transitory computer-readable medium described herein may further include operations, features, means, or instructions for outputting, based on the capability of the UE, an indication of a second puncturing scheme for the spinal coding scheme different from the puncturing scheme, encoding a second message according to the spinal coding scheme based on a second puncturing distribution of the second puncturing scheme, and outputting the second message encoded according to the spinal coding scheme in accordance with the second puncturing scheme.

In some examples of the method, network entities, and non-transitory computer-readable medium described herein, outputting the indication of the puncturing scheme for the spinal coding scheme may include operations, features, means, or instructions for outputting one of a radio resource control message or a MAC-CE indicating the puncturing scheme.

In some examples of the method, network entities, and non-transitory computer-readable medium described herein, the puncturing distribution may be based on an average number of consecutive punctured symbols, an average number of spines of the spinal coding scheme, a growth factor associated with one or more puncturing locations, or a combination thereof.

Details of one or more implementations of the subject matter described in this disclosure are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of a wireless communications system that supports improved puncturing scheme for spinal codes in accordance with one or more aspects of the present disclosure.

FIG. 2 shows an example of a wireless communications system that supports improved puncturing scheme for spinal codes in accordance with one or more aspects of the present disclosure.

FIG. 3 shows an example of a spinal coding diagram that supports improved puncturing scheme for spinal codes in accordance with one or more aspects of the present disclosure.

FIG. 4 shows an example of a puncturing scheme that supports improved puncturing scheme for spinal codes in accordance with one or more aspects of the present disclosure.

FIG. 5 shows an example of a puncturing scheme that supports improved puncturing scheme for spinal codes in accordance with one or more aspects of the present disclosure.

FIG. 6 shows an example of a process flow diagram that supports improved puncturing scheme for spinal codes in accordance with one or more aspects of the present disclosure.

FIGS. 7 and 8 show block diagrams of devices that support improved puncturing scheme for spinal codes in accordance with one or more aspects of the present disclosure.

FIG. 9 shows a block diagram of a communications manager that supports improved puncturing scheme for spinal codes in accordance with one or more aspects of the present disclosure.

FIG. 10 shows a diagram of a system including a device that supports improved puncturing scheme for spinal codes in accordance with one or more aspects of the present disclosure.

FIGS. 11 and 12 show block diagrams of devices that support improved puncturing scheme for spinal codes in accordance with one or more aspects of the present disclosure.

FIG. 13 shows a block diagram of a communications manager that supports improved puncturing scheme for spinal codes in accordance with one or more aspects of the present disclosure.

FIG. 14 shows a diagram of a system including a device that supports improved puncturing scheme for spinal codes in accordance with one or more aspects of the present disclosure.

FIGS. 15 through 18 show flowcharts illustrating methods that support improved puncturing scheme for spinal codes in accordance with one or more aspects of the present disclosure.

### DETAILED DESCRIPTION

In some wireless communications systems, communicating devices may use a spinal coding scheme. A spinal coding scheme may include multiple coding stages across which different cumulative portions of a message are encoded or decoded. Spinal coding includes combining a set of bits, or a spine, and a portion of a message to generate an output of an encoded set of bits. The encoding may be repeated, inputting another message segment and another spine to output an encoded message that is a combination of the previous message segments and spines. With each additional encoding, the complexity increases. To decode the spinal encoded message, a set of symbols may be selected to be transmitted or not be transmitted. Each symbol may be associated with a spine. A puncturing scheme identifies the symbols to be ‘punctured’ or not transmitted. To decode the symbols, a bubble decoding algorithm may use a pruned breadth-first search approach, where the possibilities become greater with each symbol. Decoding spinal codes can quickly become complex and impractical to implement.

Techniques described herein provide for a puncturing scheme that reduces the complexity of decoding spinal codes. The improved puncturing scheme includes uniformly distributing the punctures, and prioritizing puncturing at the beginning of the message. The network entity may encode a message according to a puncturing scheme, and may indicate the puncturing scheme and the encoded message to the UE. The UE may receive the encoded message and decode according to the puncturing scheme.

Aspects of the disclosure are initially described in the context of wireless communications systems. Aspects of the disclosure are further illustrated by and described with reference to a spinal coding diagram, puncturing schemes, and a process flow diagram. Aspects of the disclosure are further illustrated by and described with reference to apparatus diagrams, system diagrams, and flowcharts that relate to improved puncturing scheme for spinal codes.

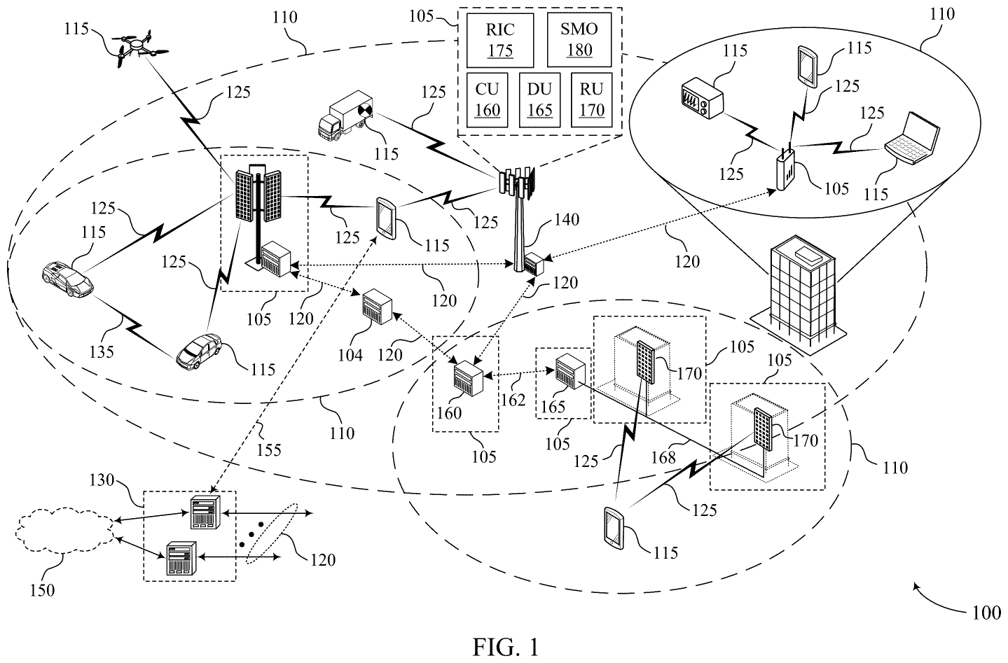

FIG. 1 shows an example of a wireless communications system 100 that supports improved puncturing scheme for spinal codes in accordance with one or more aspects of the present disclosure. The wireless communications system 100 may include one or more devices, such as one or more network devices (e.g., network entities 105), one or more UEs 115, and a core network 130. In some examples, the wireless communications system 100 may be a Long Term Evolution (LTE) network, an LTE-Advanced (LTE-A) network, an LTE-A Pro network, a New Radio (NR) network, or a network operating in accordance with other systems and radio technologies, including future systems and radio technologies not explicitly mentioned herein.

The network entities 105 may be dispersed throughout a geographic area to form the wireless communications system 100 and may include devices in different forms or having different capabilities. In various examples, a network entity 105 may be referred to as a network element, a mobility element, a radio access network (RAN) node, or network equipment, among other nomenclature. In some examples, network entities 105 and UEs 115 may wirelessly communicate via communication link(s) 125 (e.g., a radio frequency (RF) access link). For example, a network entity 105 may support a coverage area 110 (e.g., a geographic coverage area) over which the UEs 115 and the network entity 105 may establish the communication link(s) 125. The coverage area 110 may be an example of a geographic area over which a network entity 105 and a UE 115 may support the communication of signals according to one or more radio access technologies (RATs).

The UEs 115 may be dispersed throughout a coverage area 110 of the wireless communications system 100, and each UE 115 may be stationary, or mobile, or both at different times. The UEs 115 may be devices in different forms or having different capabilities. Some example UEs 115 are illustrated in FIG. 1. The UEs 115 described herein may be capable of supporting communications with various types of devices in the wireless communications system 100 (e.g., other wireless communication devices, including UEs 115 or network entities 105), as shown in FIG. 1.

As described herein, a node of the wireless communications system 100, which may be referred to as a network node, or a wireless node, may be a network entity 105 (e.g., any network entity described herein), a UE 115 (e.g., any UE described herein), a network controller, an apparatus, a device, a computing system, one or more components, or another suitable processing entity configured to perform any of the techniques described herein. For example, a node may be a UE 115. As another example, a node may be a network entity 105. As another example, a first node may be configured to communicate with a second node or a third node. In one aspect of this example, the first node may be a UE 115, the second node may be a network entity 105, and the third node may be a UE 115. In another aspect of this example, the first node may be a UE 115, the second node may be a network entity 105, and the third node may be a network entity 105. In yet other aspects of this example, the first, second, and third nodes may be different relative to these examples. Similarly, reference to a UE 115, network entity 105, apparatus, device, computing system, or the like may include disclosure of the UE 115, network entity 105, apparatus, device, computing system, or the like being a node. For example, disclosure that a UE 115 is configured to receive information from a network entity 105 also discloses that a first node is configured to receive information from a second node.

In some examples, network entities 105 may communicate with a core network 130, or with one another, or both. For example, network entities 105 may communicate with the core network 130 via backhaul communication link(s) 120 (e.g., in accordance with an S1, N2, N3, or other interface protocol). In some examples, network entities 105 may communicate with one another via backhaul communication link(s) 120 (e.g., in accordance with an X2, Xn, or other interface protocol) either directly (e.g., directly between network entities 105) or indirectly (e.g., via the core network 130). In some examples, network entities 105 may communicate with one another via a midhaul communication link 162 (e.g., in accordance with a midhaul interface protocol) or a fronthaul communication link 168 (e.g., in accordance with a fronthaul interface protocol), or any combination thereof. The backhaul communication link(s) 120, midhaul communication links 162, or fronthaul communication links 168 may be or include one or more wired links (e.g., an electrical link, an optical fiber link) or one or more wireless links (e.g., a radio link, a wireless optical link), among other examples or various combinations thereof. A UE 115 may communicate with the core network 130 via a communication link 155.

One or more of the network entities 105 or network equipment described herein may include or may be referred to as a base station 140 (e.g., a base transceiver station, a radio base station, an NR base station, an access point, a radio transceiver, a NodeB, an eNodeB (eNB), a next-generation NodeB or giga-NodeB (either of which may be referred to as a gNB), a 5G NB, a next-generation eNB (ng-eNB), a Home NodeB, a Home eNodeB, or other suitable terminology). In some examples, a network entity 105 (e.g., a base station 140) may be implemented in an aggregated (e.g., monolithic, standalone) base station architecture, which may be configured to utilize a protocol stack that is physically or logically integrated within one network entity (e.g., a network entity 105 or a single RAN node, such as a base station 140).

In some examples, a network entity 105 may be implemented in a disaggregated architecture (e.g., a disaggregated base station architecture, a disaggregated RAN architecture), which may be configured to utilize a protocol stack that is physically or logically distributed among multiple network entities (e.g., network entities 105), such as an integrated access and backhaul (IAB) network, an open RAN (O-RAN) (e.g., a network configuration sponsored by the O-RAN Alliance), or a virtualized RAN (vRAN) (e.g., a cloud RAN (C-RAN)). For example, a network entity 105 may include one or more of a central unit (CU), such as a CU 160, a distributed unit (DU), such as a DU 165, a radio unit (RU), such as an RU 170, a RAN Intelligent Controller (RIC), such as an RIC 175 (e.g., a Near-Real Time RIC (Near-RT RIC), a Non-Real Time RIC (Non-RT RIC)), a Service Management and Orchestration (SMO) system, such as an SMO system 180, or any combination thereof. An RU 170 may also be referred to as a radio head, a smart radio head, a remote radio head (RRH), a remote radio unit (RRU), or a transmission reception point (TRP). One or more components of the network entities 105 in a disaggregated RAN architecture may be co-located, or one or more components of the network entities 105 may be located in distributed locations (e.g., separate physical locations). In some examples, one or more of the network entities 105 of a disaggregated RAN architecture may be implemented as virtual units (e.g., a virtual CU (VCU), a virtual DU (VDU), a virtual RU (VRU)).

The split of functionality between a CU 160, a DU 165, and an RU 170 is flexible and may support different functionalities depending on which functions (e.g., network layer functions, protocol layer functions, baseband functions, RF functions, or any combinations thereof) are performed at a CU 160, a DU 165, or an RU 170. For example, a functional split of a protocol stack may be employed between a CU 160 and a DU 165 such that the CU 160 may support one or more layers of the protocol stack and the DU 165 may support one or more different layers of the protocol stack. In some examples, the CU 160 may host upper protocol layer (e.g., layer 3 (L3), layer 2 (L2)) functionality and signaling (e.g., Radio Resource Control (RRC), service data adaptation protocol (SDAP), Packet Data Convergence Protocol (PDCP)). The CU 160 (e.g., one or more CUs) may be connected to a DU 165 (e.g., one or more DUs) or an RU 170 (e.g., one or more RUs), or some combination thereof, and the DUs 165, RUs 170, or both may host lower protocol layers, such as layer 1 (L1) (e.g., physical (PHY) layer) or L2 (e.g., radio link control (RLC) layer, medium access control (MAC) layer) functionality and signaling, and may each be at least partially controlled by the CU 160. Additionally, or alternatively, a functional split of the protocol stack may be employed between a DU 165 and an RU 170 such that the DU 165 may support one or more layers of the protocol stack and the RU 170 may support one or more different layers of the protocol stack. The DU 165 may support one or multiple different cells (e.g., via one or multiple different RUs, such as an RU 170). In some cases, a functional split between a CU 160 and a DU 165 or between a DU 165 and an RU 170 may be within a protocol layer (e.g., some functions for a protocol layer may be performed by one of a CU 160, a DU 165, or an RU 170, while other functions of the protocol layer are performed by a different one of the CU 160, the DU 165, or the RU 170). A CU 160 may be functionally split further into CU control plane (CU-CP) and CU user plane (CU-UP) functions. A CU 160 may be connected to a DU 165 via a midhaul communication link 162 (e.g., F1, F1-c, F1-u), and a DU 165 may be connected to an RU 170 via a fronthaul communication link 168 (e.g., open fronthaul (FH) interface). In some examples, a midhaul communication link 162 or a fronthaul communication link 168 may be implemented in accordance with an interface (e.g., a channel) between layers of a protocol stack supported by respective network entities (e.g., one or more of the network entities 105) that are in communication via such communication links.

In some wireless communications systems (e.g., the wireless communications system 100), infrastructure and spectral resources for radio access may support wireless backhaul link capabilities to supplement wired backhaul connections, providing an IAB network architecture (e.g., to a core network 130). In some cases, in an IAB network, one or more of the network entities 105 (e.g., network entities 105 or IAB node(s) 104) may be partially controlled by each other. The IAB node(s) 104 may be referred to as a donor entity or an IAB donor. A DU 165 or an RU 170 may be partially controlled by a CU 160 associated with a network entity 105 or base station 140 (such as a donor network entity or a donor base station). The one or more donor entities (e.g., IAB donors) may be in communication with one or more additional devices (e.g., IAB node(s) 104) via supported access and backhaul links (e.g., backhaul communication link(s) 120). IAB node(s) 104 may include an IAB mobile termination (IAB-MT) controlled (e.g., scheduled) by one or more DUs (e.g., DUs 165) of a coupled IAB donor. An IAB-MT may be equipped with an independent set of antennas for relay of communications with UEs 115 or may share the same antennas (e.g., of an RU 170) of IAB node(s) 104 used for access via the DU 165 of the IAB node(s) 104 (e.g., referred to as virtual IAB-MT (vIAB-MT)). In some examples, the IAB node(s) 104 may include one or more DUs (e.g., DUs 165) that support communication links with additional entities (e.g., IAB node(s) 104, UEs 115) within the relay chain or configuration of the access network (e.g., downstream). In such cases, one or more components of the disaggregated RAN architecture (e.g., the IAB node(s) 104 or components of the IAB node(s) 104) may be configured to operate according to the techniques described herein.

In the case of the techniques described herein applied in the context of a disaggregated RAN architecture, one or more components of the disaggregated RAN architecture may be configured to support test as described herein. For example, some operations described as being performed by a UE 115 or a network entity 105 (e.g., a base station 140) may additionally, or alternatively, be performed by one or more components of the disaggregated RAN architecture (e.g., components such as an IAB node, a DU 165, a CU 160, an RU 170, an RIC 175, an SMO system 180).

A UE 115 may include or may be referred to as a mobile device, a wireless device, a remote device, a handheld device, or a subscriber device, or some other suitable terminology, where the “device” may also be referred to as a unit, a station, a terminal, or a client, among other examples. A UE 115 may also include or may be referred to as a personal electronic device such as a cellular phone, a personal digital assistant (PDA), a tablet computer, a laptop computer, or a personal computer. In some examples, a UE 115 may include or be referred to as a wireless local loop (WLL) station, an Internet of Things (IoT) device, an Internet of Everything (IoE) device, or a machine type communications (MTC) device, among other examples, which may be implemented in various objects such as appliances, vehicles, or meters, among other examples.

The UEs 115 described herein may be able to communicate with various types of devices, such as UEs 115 that may sometimes operate as relays, as well as the network entities 105 and the network equipment including macro eNBs or gNBs, small cell eNBs or gNBs, or relay base stations, among other examples, as shown in FIG. 1.

The UEs 115 and the network entities 105 may wirelessly communicate with one another via the communication link(s) 125 (e.g., one or more access links) using resources associated with one or more carriers. The term “carrier” may refer to a set of RF spectrum resources having a defined PHY layer structure for supporting the communication link(s) 125. For example, a carrier used for the communication link(s) 125 may include a portion of an RF spectrum band (e.g., a bandwidth part (BWP)) that is operated according to one or more PHY layer channels for a given RAT (e.g., LTE, LTE-A, LTE-A Pro, NR). Each PHY layer channel may carry acquisition signaling (e.g., synchronization signals, system information), control signaling that coordinates operation for the carrier, user data, or other signaling. The wireless communications system 100 may support communication with a UE 115 using carrier aggregation or multi-carrier operation. A UE 115 may be configured with multiple downlink component carriers and one or more uplink component carriers according to a carrier aggregation configuration. Carrier aggregation may be used with both frequency division duplexing (FDD) and time division duplexing (TDD) component carriers. Communication between a network entity 105 and other devices may refer to communication between the devices and any portion (e.g., entity, sub-entity) of a network entity 105. For example, the terms “transmitting,” “receiving,” or “communicating,” when referring to a network entity 105, may refer to any portion of a network entity 105 (e.g., a base station 140, a CU 160, a DU 165, a RU 170) of a RAN communicating with another device (e.g., directly or via one or more other network entities, such as one or more of the network entities 105).

Signal waveforms transmitted via a carrier may be made up of multiple subcarriers (e.g., using multi-carrier modulation (MCM) techniques such as orthogonal frequency division multiplexing (OFDM) or discrete Fourier transform spread OFDM (DFT-S-OFDM)). In a system employing MCM techniques, a resource element may refer to resources of one symbol period (e.g., a duration of one modulation symbol) and one subcarrier, in which case the symbol period and subcarrier spacing may be inversely related. The quantity of bits carried by each resource element may depend on the modulation scheme (e.g., the order of the modulation scheme, the coding rate of the modulation scheme, or both), such that a relatively higher quantity of resource elements (e.g., in a transmission duration) and a relatively higher order of a modulation scheme may correspond to a relatively higher rate of communication. A wireless communications resource may refer to a combination of an RF spectrum resource, a time resource, and a spatial resource (e.g., a spatial layer, a beam), and the use of multiple spatial resources may increase the data rate or data integrity for communications with a UE 115.

The time intervals for the network entities 105 or the UEs 115 may be expressed in multiples of a basic time unit which may, for example, refer to a sampling period of Tₛ=1/(Δfₘₐₓ·N_{f}) seconds, for which Δfₘₐₓ may represent a supported subcarrier spacing, and N_{f} may represent a supported discrete Fourier transform (DFT) size. Time intervals of a communications resource may be organized according to radio frames each having a specified duration (e.g., 10 milliseconds (ms)). Each radio frame may be identified by a system frame number (SFN) (e.g., ranging from 0 to 1023).

Each frame may include multiple consecutively-numbered subframes or slots, and each subframe or slot may have the same duration. In some examples, a frame may be divided (e.g., in the time domain) into subframes, and each subframe may be further divided into a quantity of slots. Alternatively, each frame may include a variable quantity of slots, and the quantity of slots may depend on subcarrier spacing. Each slot may include a quantity of symbol periods (e.g., depending on the length of the cyclic prefix prepended to each symbol period). In some wireless communications systems, such as the wireless communications system 100, a slot may further be divided into multiple mini-slots associated with one or more symbols. Excluding the cyclic prefix, each symbol period may be associated with one or more (e.g., N_{f}) sampling periods. The duration of a symbol period may depend on the subcarrier spacing or frequency band of operation.

A subframe, a slot, a mini-slot, or a symbol may be the smallest scheduling unit (e.g., in the time domain) of the wireless communications system 100 and may be referred to as a transmission time interval (TTI). In some examples, the TTI duration (e.g., a quantity of symbol periods in a TTI) may be variable. Additionally, or alternatively, the smallest scheduling unit of the wireless communications system 100 may be dynamically selected (e.g., in bursts of shortened TTIs (STTIs)).

Physical channels may be multiplexed for communication using a carrier according to various techniques. A physical control channel and a physical data channel may be multiplexed for signaling via a downlink carrier, for example, using one or more of time division multiplexing (TDM) techniques, frequency division multiplexing (FDM) techniques, or hybrid TDM-FDM techniques. A control region (e.g., a control resource set (CORESET)) for a physical control channel may be defined by a set of symbol periods and may extend across the system bandwidth or a subset of the system bandwidth of the carrier. One or more control regions (e.g., CORESETs) may be configured for a set of the UEs 115. For example, one or more of the UEs 115 may monitor or search control regions for control information according to one or more search space sets, and each search space set may include one or multiple control channel candidates in one or more aggregation levels arranged in a cascaded manner. An aggregation level for a control channel candidate may refer to an amount of control channel resources (e.g., control channel elements (CCEs)) associated with encoded information for a control information format having a given payload size. Search space sets may include common search space sets configured for sending control information to UEs 115 (e.g., one or more UEs) or may include UE-specific search space sets for sending control information to a UE 115 (e.g., a specific UE).

In some examples, a network entity 105 (e.g., a base station 140, an RU 170) may be movable and therefore provide communication coverage for a moving coverage area, such as the coverage area 110. In some examples, coverage areas 110 (e.g., different coverage areas) associated with different technologies may overlap, but the coverage areas 110 (e.g., different coverage areas) may be supported by the same network entity (e.g., a network entity 105). In some other examples, overlapping coverage areas, such as a coverage area 110, associated with different technologies may be supported by different network entities (e.g., the network entities 105). The wireless communications system 100 may include, for example, a heterogeneous network in which different types of the network entities 105 support communications for coverage areas 110 (e.g., different coverage areas) using the same or different RATs.

The wireless communications system 100 may be configured to support ultra-reliable communications or low-latency communications, or various combinations thereof. For example, the wireless communications system 100 may be configured to support ultra-reliable low-latency communications (URLLC). The UEs 115 may be designed to support ultra-reliable, low-latency, or critical functions. Ultra-reliable communications may include private communication or group communication and may be supported by one or more services such as push-to-talk, video, or data. Support for ultra-reliable, low-latency functions may include prioritization of services, and such services may be used for public safety or general commercial applications. The terms ultra-reliable, low-latency, and ultra-reliable low-latency may be used interchangeably herein.

In some examples, a UE 115 may be configured to support communicating directly with other UEs (e.g., one or more of the UEs 115) via a device-to-device (D2D) communication link, such as a D2D communication link 135 (e.g., in accordance with a peer-to-peer (P2P), D2D, or sidelink protocol). In some examples, one or more UEs 115 of a group that are performing D2D communications may be within the coverage area 110 of a network entity 105 (e.g., a base station 140, an RU 170), which may support aspects of such D2D communications being configured by (e.g., scheduled by) the network entity 105. In some examples, one or more UEs 115 of such a group may be outside the coverage area 110 of a network entity 105 or may be otherwise unable to or not configured to receive transmissions from a network entity 105. In some examples, groups of the UEs 115 communicating via D2D communications may support a one-to-many (1:M) system in which each UE 115 transmits to one or more of the UEs 115 in the group. In some examples, a network entity 105 may facilitate the scheduling of resources for D2D communications. In some other examples, D2D communications may be carried out between the UEs 115 without an involvement of a network entity 105.

The core network 130 may provide user authentication, access authorization, tracking, Internet Protocol (IP) connectivity, and other access, routing, or mobility functions. The core network 130 may be an evolved packet core (EPC) or 5G core (5GC), which may include at least one control plane entity that manages access and mobility (e.g., a mobility management entity (MME), an access and mobility management function (AMF)) and at least one user plane entity that routes packets or interconnects to external networks (e.g., a serving gateway (S-GW), a Packet Data Network (PDN) gateway (P-GW), or a user plane function (UPF)). The control plane entity may manage non-access stratum (NAS) functions such as mobility, authentication, and bearer management for the UEs 115 served by the network entities 105 (e.g., base stations 140) associated with the core network 130. User IP packets may be transferred through the user plane entity, which may provide IP address allocation as well as other functions. The user plane entity may be connected to IP services 150 for one or more network operators. The IP services 150 may include access to the Internet, Intranet(s), an IP Multimedia Subsystem (IMS), or a Packet-Switched Streaming Service.

The wireless communications system 100 may operate using one or more frequency bands, which may be in the range of 300 megahertz (MHz) to 300 gigahertz (GHz). Generally, the region from 300 MHz to 3 GHz is known as the ultra-high frequency (UHF) region or decimeter band because the wavelengths range from approximately one decimeter to one meter in length. UHF waves may be blocked or redirected by buildings and environmental features, which may be referred to as clusters, but the waves may penetrate structures sufficiently for a macro cell to provide service to the UEs 115 located indoors. Communications using UHF waves may be associated with smaller antennas and shorter ranges (e.g., less than one hundred kilometers) compared to communications using the smaller frequencies and longer waves of the high frequency (HF) or very high frequency (VHF) portion of the spectrum below 300 MHz.

The wireless communications system 100 may utilize both licensed and unlicensed RF spectrum bands. For example, the wireless communications system 100 may employ License Assisted Access (LAA), LTE-Unlicensed (LTE-U) RAT, or NR technology using an unlicensed band such as the 5 GHz industrial, scientific, and medical (ISM) band. While operating using unlicensed RF spectrum bands, devices such as the network entities 105 and the UEs 115 may employ carrier sensing for collision detection and avoidance. In some examples, operations using unlicensed bands may be based on a carrier aggregation configuration in conjunction with component carriers operating using a licensed band (e.g., LAA). Operations using unlicensed spectrum may include downlink transmissions, uplink transmissions, P2P transmissions, or D2D transmissions, among other examples.

A network entity 105 (e.g., a base station 140, an RU 170) or a UE 115 may be equipped with multiple antennas, which may be used to employ techniques such as transmit diversity, receive diversity, multiple-input multiple-output (MIMO) communications, or beamforming. The antennas of a network entity 105 or a UE 115 may be located within one or more antenna arrays or antenna panels, which may support MIMO operations or transmit or receive beamforming. For example, one or more base station antennas or antenna arrays may be co-located at an antenna assembly, such as an antenna tower. In some examples, antennas or antenna arrays associated with a network entity 105 may be located at diverse geographic locations. A network entity 105 may include an antenna array with a set of rows and columns of antenna ports that the network entity 105 may use to support beamforming of communications with a UE 115. Likewise, a UE 115 may include one or more antenna arrays that may support various MIMO or beamforming operations. Additionally, or alternatively, an antenna panel may support RF beamforming for a signal transmitted via an antenna port.

Beamforming, which may also be referred to as spatial filtering, directional transmission, or directional reception, is a signal processing technique that may be used at a transmitting device or a receiving device (e.g., a network entity 105, a UE 115) to shape or steer an antenna beam (e.g., a transmit beam, a receive beam) along a spatial path between the transmitting device and the receiving device. Beamforming may be achieved by combining the signals communicated via antenna elements of an antenna array such that some signals propagating along particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (e.g., with respect to the antenna array of the transmitting device or receiving device, or with respect to some other orientation).

Wireless communications system 100 may support a puncturing scheme that reduces the complexity of decoding spinal codes. The improved puncturing scheme includes uniformly distributing the punctures, and prioritizing puncturing at the beginning of the message. The network entity 105 may encode a message according to a puncturing scheme, and indicate the puncturing scheme and the encoded message to the UE 115. The UE 115 may receive the encoded message and decode according to the puncturing scheme. Further details regarding the encoding and decoding according to the improved puncturing scheme are described herein.

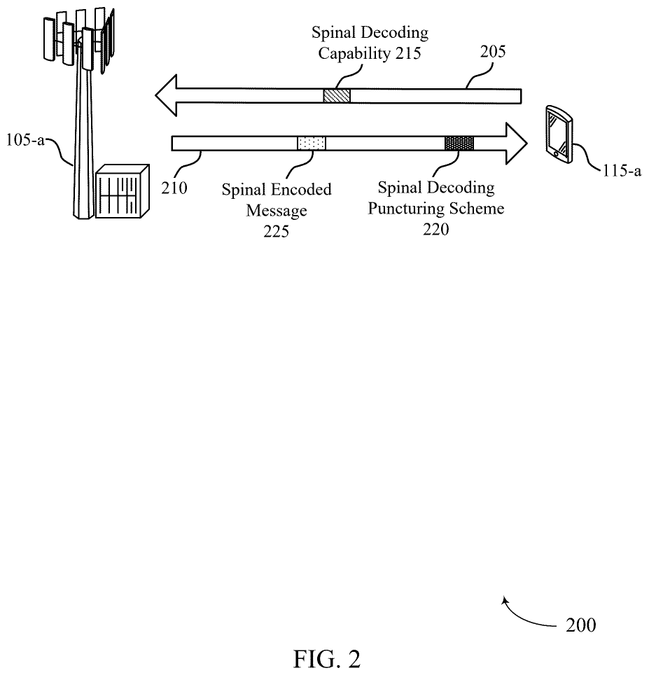

FIG. 2 shows an example of a wireless communications system 200 that supports improved puncturing scheme for spinal codes in accordance with one or more aspects of the present disclosure. The wireless communications system 200 describes the communications between a UE 115-a and a network entity 105-a according to the improved puncturing scheme for spinal codes. The UE 115-a and the network entity 105-a may be examples of the UE 115 and the network entity 105 as described with reference to FIG. 1.

As described with reference to FIG. 2, the network entity 105-a may communicate (e.g., transmit, output) with the UE 115-a via a communication link 205 (e.g., a downlink channel, a physical downlink control channel (PDCCH), a physical downlink shared channel (PDSCH), among other examples). The UE 115-a may communicate (e.g., transmit, output) with the network entity 105-a via a communication link 210 (e.g., an uplink channel, a physical uplink control channel (PUCCH), a physical uplink shared channel (PUSCH), among other examples).

In some wireless communications systems, such as 5G, different coding schemes have been introduced. For example, low-density parity-check (LDPC) code may be applied to PDSCH and polar coding may be applied to PDCCH. Other coding schemes may be applied to other wireless communications systems, such as future wireless communications (e.g., 6G). For example, spinal coding may be used for message communication.

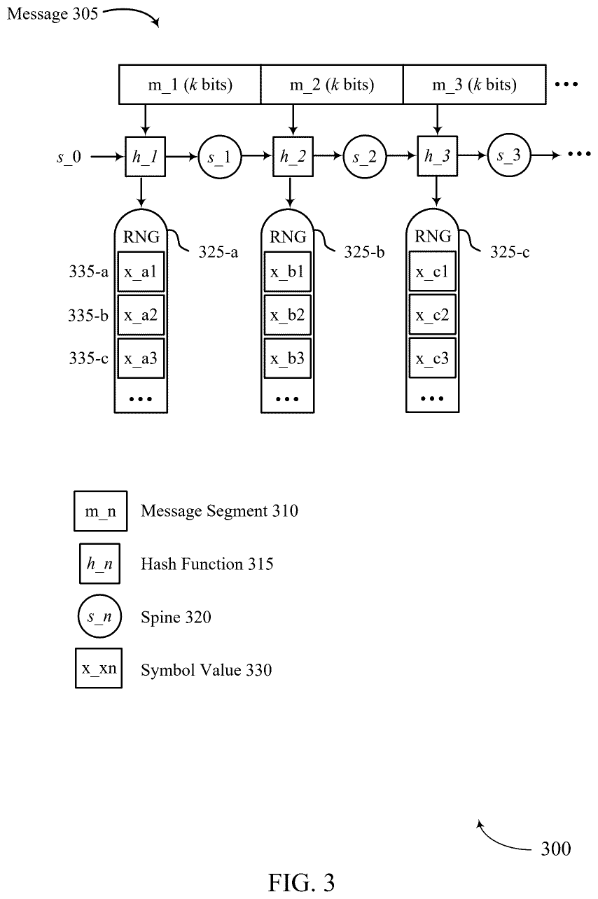

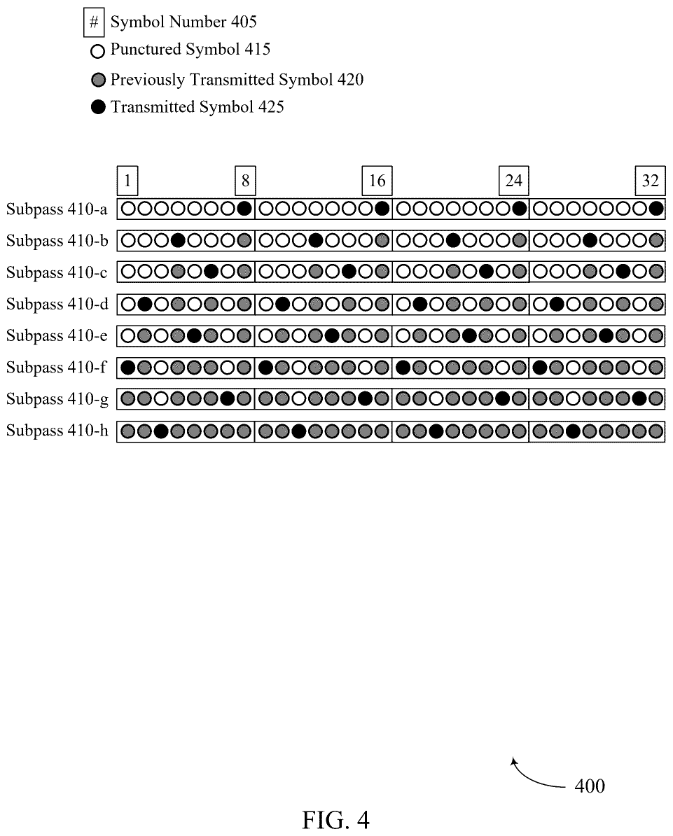

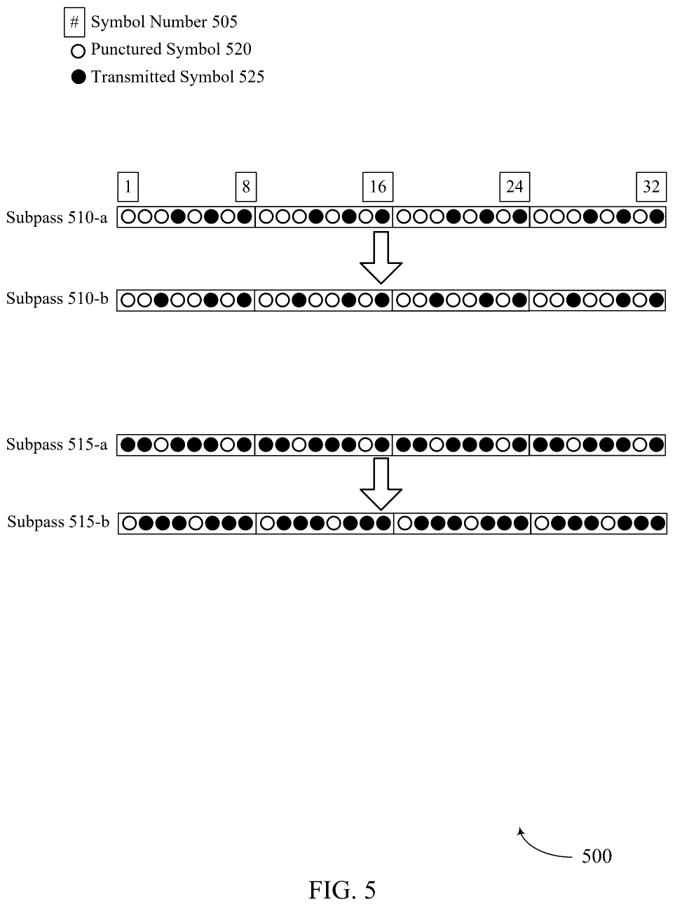

Spinal coding includes a spinal code, which may be efficient for short block length and high spectral efficiency. Spinal coding may be used in a rateless scheme (e.g., a rateless coding scheme), or may be used in other (e.g., MCS based) coding schemes as well. Spinal coding schemes include combining spines, or a set of bits, and portions of a message, to output a spinal encoded message 225. Spinal coding is further described with reference to FIG. 3. Decoding may be at least partially based on a puncturing scheme, which is further described with reference to FIGS. 4 and 5.

The UE 115-a may transmit a spinal decoding capability 215 indicating that the UE 115-a is capable of decoding messages that have been encoded according to a spinal coding scheme. The network entity 105-a may receive the spinal decoding capability 215, and encode a message accordingly. The network entity 105-a transmit a spinal decoding puncturing scheme 220 and a spinal encoded message 225. The UE 115-a may decode the spinal encoded message 225 according to the spinal decoding puncturing scheme 220. The spinal decoding puncturing scheme 220 may be an improved puncturing scheme, such as prioritizing even distribution of punctures, puncturing the beginning of the tree, or both.

FIG. 3 shows an example of a spinal coding diagram 300 that supports improved puncturing scheme for spinal codes in accordance with one or more aspects of the present disclosure. The spinal coding diagram 300 may implement or be implemented to realize aspects of the wireless communications system 100 and the wireless communications system 200. The spinal coding diagram 300 describes the encoding of a message 305 according to a spinal coding scheme.

The spinal coding diagram 300 may be an example of a spinal code encoding scheme or may otherwise illustrate spinal coding. Spinal codes may be a class of rateless codes that are compatible with time-varying channel conditions in a natural or simple way without use of an explicit bit rate selection. Spinal coding may be associated with an absence or lack of explicit signaling for bit rates of a transmission. For example, communicating devices may refrain from transmitting an indication of one or more aspects of an MCS while implementing rateless coding. Instead, a network entity, an encoder, or another transmitting device, may use rateless codes, such as spinal codes, to perform an initial transmission of the message 305 at a high bit rate (such as a relatively highest bit rate). In other examples, spinal coding diagram 300 may support non-rateless coding schemes, such as MCS-based coding schemes.

In accordance with encoding techniques that implement spinal codes, the network entity (such as the network entity 105, an encoder, or another transmitting device) may perform the encoding of the message 305. The network entity may include an encoder that apply a hash function 315 (e.g., a first hash function h_1, a second hash function h_2, a third hash function h_3) and a random number generator (RNG) 325 (e.g., RNG 325-a, RNG 325-b, RNG 325-c) sequentially or cumulatively to message segments 310 (e.g., a first message segment m_1, a second message segment m_2, a third message segment m_3) to produce a spine 320. The spine 320 (e.g., a first spine s_1, a second spine s_2, a third spine s_3), may be a sequence of coded bits and symbols (such as modulation symbols). In some aspects, the encoder may employ the encoding such that two input messages that differ in even one bit lead to different coded sequences after a point at which the two input messages differ, which may provide resilience to noise or bit errors.

The spinal coding scheme may include sequential encoding of a message 305 of n bits across a set of message segments 310 (e.g., m_1, m_2, m_3, etc.) of k bits each. The message 305 may be divided into a set of message segments 310 and be cumulatively encoded across multiple stages. That is, each stage involves an encoding with an additional next message segment 310. For example, the encoding of the second message segment m_2 includes the previously encoded first message segment m_1. In various implementations, k may be the same for each message segment 310 or may be different for some message segments 310 (such that some message segments 310 may include different quantities of bits than other message segments 310). The set of message segments 310 may accordingly include a quantity of n/k message segments 310.

The encoder may include, for each stage of the spinal coding scheme, a hash function 315 and a numeric transposition function, such as the RNG 325, or other scrambling function. The hash functions 315 and the RNGs 325 of the spinal coding scheme may be known to the network entity and the UE. For example, the hash functions 315 and the RNGs 325 may be pre-configured (such as pre-loaded) at both the network entity and the UE, or one or more aspects or configurations of such functions may be signaled between the network entity and the UE.

In some aspects, an encoder of the network entity or a decoder of the UE, or both, may combine a hash function 315 with an RNG 325 into a single or same processing block. Moreover, although each instance of a hash function 315 and each instance of an RNG 325 are illustrated separately, in some implementations, the separately illustrated instances of a hash function 315, or an RNG 325, or both may be performed by a same set of functional instructions, or by a same set of processing circuitry, which may be performed with different inputs to provide different outputs.

The encoder may implement a hash function 315 with two inputs: a spine 320 and a message segment 310. A spine 320 may be referred to as an encoded value and may be an example of a v bit state, and a message segment 310 may include a portion, chunk, or quantity of k bits of the message 305. The encoder may obtain, as an output of a hash function 315, a new spine 320 (a new encoded value or a new v bit state). To begin, hash function 315 may receive a first input of s_0, which may be an initial spine 320, of size v bits and a first message segment m_1 of size k bits and may output a first spine s_1 of size v bits.

A hash function 315 may be represented by Equation 1 and a value of a spine 320 may be represented by Equation 2, where an index i may refer to or indicate a coding index or stage (such as an encoding stage or a decoding stage) and mi may refer a message segment 310 corresponding to that coding index or stage i. In some aspects, s₀ (or s_0) may be an initial input spine 320 or some other initial value and may be set equal to zero, or to some other default or pre-configured value. Additionally, or alternatively, the network entity and the UE may coordinate (such as via an exchange of one or more signals) on a value of so. In some implementations, for example, an encoder may set or configure a value of so to be equal to an identifying value or parameter associated receiving device, such as an RNTI, which may support various techniques for partial decoding of a search space by various receiving devices in accordance with examples as disclosed herein. In some aspects, an output of a hash function 315 may include 32 bits (such that v=32).

$$h : {\{ 0 , 1 \}}^{v} \times {\{ 0 , 1 \}}^{k} \to {\{ 0 , 1 \}}^{v} \qquad ( 1 )$$

$${s}_{i} = h ( {s}_{i - 1} , {\overline{m}}_{i} ) \qquad ( 2 )$$

The encoder may generate a spine 320 of v bit states by sequentially or cumulatively hashing together groups of k bits from the input message 305 and, in some implementations, may refrain from adding any redundancy bits (as may be added for some other coding schemes). For example, the encoder may obtain a first spine s_1 as an output of a first hash function h_1, may obtain a second spine s_2 as an output of a second hash function h_2, and may obtain a third spine s_3 as an output of a third hash function h_3. Further, in some aspects, the encoder may use or otherwise reach a hash function 315 with a low probability of hash collisions (in part as a result of the sequential or cumulative hashing of groups or segments of k bits from the input message 305).

The encoder may generate a spine 320 for each message segment 310 and may use each of the n/k spines 320 as a seed or input into a respective instance of an RNG 325. A spine 320 may include or otherwise convey information associated with a message segment 310 of a same coding indices or stage as well as information associated with message segments 310 of preceding coding indices or stages. For instance, the first spine s_1 may include or otherwise convey information associated with the first message segment m_1 (and a seed value s_0, such as a device identifier, where applicable), the second spine s_2 may include or otherwise convey information associated with the first and second message segments m_1 and m_2, and the third spine s_3 may include or otherwise convey information associated with the first, second, and third message segments m_1, m_2, and m_3.

As such, a last or final spine 320 may include encoded information associated with the entire message 305 and an encoder may, in some scenarios, transmit a signal associated with the last spine 320 (and suppress transmission of signals associated with other spines 320) to achieve an upper limit bit or channel rate (because the transmission of the signal associated with the last spine 320 may convey the entire message 305 via a single channel use). Such scenarios in which the encoder exclusively transmits a signal associated with the last spine 320 may include scenarios of a relatively high SNR (such as an SNR greater than a threshold SNR or a theoretically infinite SNR) or scenarios associated with a relatively high constellation order (such as a constellation order greater than a threshold constellation order).

Each instance of an RNG 325, in accordance with receiving a spine 320 as an input, may output a symbol value 330 (such as a sequence of c-bit numbers or a sequence of c bits). As such, an RNG 325 may receive a value of a spine 320 as an input (having a size of v bits) and may apply some numeric transposition function [symbol] to the value of the spine 320. Such a numeric transposition function [symbol] may be an RNG, a pseudo-random RNG, a mapping function, a scrambling function, a scaling function, or any combination thereof. In some aspects, an RNG 325 may be represented by Equation 3.

$$RNG : {\{ 0 , 1 \}}^{v} \times ℕ \to {\{ 0 , 1 \}}^{c} \qquad ( 3 )$$

In some implementations, a symbol value 330 may be an example of, or may be otherwise associated with (such as mapped to) one or more modulation symbols, such as an in-phase and quadrature (IQ) constellation symbol or point, or other types of modulation symbols, such as a pulse-amplitude modulation (PAM) symbol. In some aspects, an IQ constellation symbol may be or may be associated with two orthogonal PAM symbols. In some other implementations, the encoder may convert a symbol value 330 into an IQ constellation symbol or point (such as via an IQ constellation mapping function). In implementations in which the encoder converts a symbol value 330 into an IQ constellation symbol or point, the encoder may use an IQ constellation mapping function to generate a transmitted symbol (such as a constellation symbol or a modulation symbol) from an output of an RNG 325. In such implementations, an encoder may use the IQ constellation mapping function to map each symbol value 330 to a (different) modulation symbol (which may be equivalently referred to herein as a constellation symbol or point). Thus, the spinal coding scheme may illustrate an example implementation that includes a combination of an encoding operation and a modulation operation (such as a scheme where encoding and modulation are performed jointly, a rateless encoding and modulation scheme, or an MCS coding scheme).

In some implementations, an encoder may achieve higher bit rates (without increasing a decoding cost) via a puncturing of the transmitted symbols at the transmitter side, where such transmission puncturing may refer to various techniques for performing transmissions associated with a subset of the spines 320 for a given message 305, such as refraining from performing transmissions associated with one or more spines 320 for at least in an initial transmission associated with the given message 305. For example, an encoder may transmit one or more signals associated with one or more specific spines 320 over a set of transmission occasions 335 in accordance with a transmission puncturing scheme. The transmission puncturing scheme may define or otherwise indicate which one or more spines 320 an encoder is to transmit at each of the set of transmission occasions 335. For example, an encoder may transmit a signal associated with the third spine s_3 during a transmission occasion 335-a, may transmit a signal associated with the second spine s_2 during a transmission occasion 335-b, and may transmit a signal associated with the first spine s_1 during a transmission occasion 335-c, where applicable.

Each RNG may include various symbol values 330 depending on the transmission occasion 335. For example, the RNG 325-a may output, for the input of the first spine s_1, a symbol value x_a1 (as illustrated by or denoted as an x_{a,1} or x_a,1 value) for the transmission occasion 335-a, may output a symbol value x_a2 (as illustrated by or denoted as an x_{a,2} or x_a,2 value) for the transmission occasion 335-b, and may output a symbol value x_a3 (as illustrated by or denoted as an x_{a,3} or x_a,3 value) for the transmission occasion 335-c. The RNG 325-b may output, for the input second spine s_2, a symbol value x_b1 (as illustrated by or denoted as an x_{b,1} or x_b,1 value) for the transmission occasion 335-a, output a symbol value x_b2 (as illustrated by or denoted as an x_{b,2} or x_b,2 value) for the transmission occasion 335-b, and may output a symbol value x_b3 (as illustrated by or denoted as an x_{b,3} or x_b,3 value) for the transmission occasion 335-c. The RNG 325-c may output, for the input third spine s_3, a symbol value x_c1 (as illustrated by or denoted as an x_{c,1} or x_c,1 value) for the transmission occasion 335-a, may output a symbol value x_c2 (as illustrated by or denoted as an x_{c,2} or x_c,2 value) for the transmission occasion 335-b, and may output a symbol value x_c3 (as illustrated by or denoted as an x_{c,3} or x_c,3 value) for the transmission occasion 335-c. Although a symbol value 330 is illustrated for each spine 320 at each transmission occasion 335, an encoder may refrain from generating those symbol values 330 that are not configured or scheduled for transmission, such as those spines 320 that have been punctured by a transmission puncturing scheme for a given transmission occasion 335.

As such, if the encoder transmits a signal associated with the third spine s_3 during the transmission occasion 335-a, transmits a signal associated with the second spine s_2 during the transmission occasion 335-b, and transmits a signal associated with the spine first spine s_1 during the transmission occasion 335-c, the encoder may transmit a signal associated with the symbol value x_c1 during the transmission occasion 335-a, may transmit a signal associated with the symbol value x_b2 during the transmission occasion 335-b, and may transmit a signal associated with the symbol value x_a3 during the transmission occasion 335-c. Each transmission, which may collectively be associated with or based on a transmission puncturing scheme, may use any modulation constellation, such as any one or more of a quadrature amplitude modulation (QAM) constellation, a non-square constellation, or a Gaussian constellation, among other examples.

In some examples, the encoded message may be decoded according to a bubble decoding scheme, or algorithm. Bubble decoding for spinal coding may include navigating a tree of potential messages issuing a pruned breadth-first search approach. The tree may have nodes, which represents a potential message.

A spinal encoder may apply a hash function 315 sequentially or cumulatively across multiple message segments 310, such that input messages with a common prefix also may have a common spine value (such as a common spine prefix or a common value of a spine 320 conveying information associated with the common prefix), whereas symbol values 330 produced or output by an RNG 325 from the common spine values may or may not be identical. As such, a receiving device (e.g., decoder, decoding device, UE) may use the tree structure to decompose a total distance into a summation over spines 320.

If a decoder constructs an entire ML decoding tree and computes path costs for each of the nodes (which may be referred to as leaves), the decoder may select preferred B nodes (such as the B nodes or leaves having the lowest path cost) and may trace back through the decoding tree to find that each of the B selected nodes converge to a relatively small number of common “ancestors,” where an “ancestor” may refer to a node of a decoding tree relatively closer to a root of the tree than the B selected nodes and where a common “ancestor” may refer to a node from which each of the B selected nodes can be traced back to.

Thus, a decoder may implement a bubble decoder and, instead of searching an entire decoding tree, the decoder may maintain B common ancestors (beams) and a partial decoding tree rooted at each ancestor. In some implementations, the decoder may select a node with a lowest path cost and may return a complete message corresponding to the selected node (such as a complete message conveyed by a spine 320 associated with the selected node of the decoding tree).

A width of the decoding tree may be associated with or given by the parameter k (such that the tree may expand by 2^{k} nodes or leaves at each stage). As such, the width of the decoding tree may decrease as k decreases and the decoding tree may correspondingly include more decoding stages (as a result of n/k increasing) as k decreases. Further, as the width of the decoding tree decreases and as a quantity of decoding stages increases, a latency until a next transmission (such as a next retransmission) may increase as well. Likewise, the width of the decoding tree may increase as k increases and the decoding tree may correspondingly include fewer decoding stages (as a result of n/k decreasing) as k increases. Further, as the width of the decoding tree increases and as a quantity of decoding stages decreases, a latency until a next transmission (such as a next retransmission) may decrease as well.

A decoder may generate or otherwise use a decoding tree of n/k decoding stages or levels and 2ⁿ leaves or nodes at a last or final decoding stage. A root of the decoding tree may be s_0 and may branch out to 2^{k} leaves at a first decoding stage associated with the first spine s_1. Each leaf of the first decoding stage associated with the first spine s_1 may branch out to 2^{k} leaves at a next decoding stage associated with a next spine, and eventually to a decoding stage associated with a final spine.

To manage computational complexity, a fixed number of B nodes may retained at each level, forming a group, or a beam. The decoder, receiving device, or UE may score the received symbols and candidate message according to a minimum square error (MSE) cost of the candidate message. As the number of nodes exceeds the prescribed maximum B, the decoder proceeds to the next spine only with those B nodes with lower processing costs. The upper bound for the MDE calculations of a bubble decoding process is roughly described by n/k*B, with the omission of calculation performed at the tree's initial stages.

However, bubble decoding may result in complexity. Techniques described herein provide for decoding according to an improved puncturing scheme.

FIG. 4 shows an example of a puncturing scheme 400 that supports improved puncturing scheme for spinal codes in accordance with one or more aspects of the present disclosure. The puncturing scheme 400 describes an example of a puncturing scheme for spinal coding. The puncturing scheme 400 may implement or be implemented by other figures described herein.

As described with reference to FIG. 4, the puncturing scheme may have a rate of 8k bits per channel use. Each subpass may have 32 bits, as described by the symbol numbers 405. For each subpass 410-a, 410-b, 410-c, 410-d, 410-e, 410-f, 410-g, and 410-h, the transmitter may transmit symbols for spine values. Thus, each symbol may be associated with a spine. Each subpass 410 may include punctured symbols 415, previously transmitted symbols 420, and transmitted symbols 425. The combination of transmitted symbols 425 may affect rate granularity. For example, if the number of total bits is 256, and there are eight subpasses, the number of spines per subpass is 32. Each spine may be represented by a symbol, or symbol number 405.

The total number of transmitted symbols per subpass 410 effects the effective rate granularity. Decreasing the number of transmitted symbols, or rate, increases the granularity. FIG. 4 describes an example of a bit rate of 8k, however, techniques may be applicable to other bit rates.

For subpass 410-a, a symbol is transmitted every 8 symbols. Every eight symbols may be described as a spine vector, and the transmissions from vector to vector may be continuous, or wrapped around. At subpass 410-b, the fourth symbol of every eight symbols (e.g., spine vector) is a transmitted symbol 425, the eighth is a previously transmitted symbol 420, and the transmitted symbols 425 and the previously transmitted symbols 420 are separated by three consecutive punctured symbols 415. With each subpass 410, more symbols are transmitted symbols 425 and are previously transmitted symbol 420, and fewer symbols are punctured symbols 415.

For each punctured symbol 415, the tree search size increases by a factor of 2^{k}. A growth factor may be defined by (2^{k})^{x}, where x is the number of consecutive punctured symbols 415 and k is the number of punctured symbols 415. For example, such as for subpass 410-b, there are three consecutive punctured symbols 415, and if k=4, there is a growth factor of (2^{k})³=4096. Decreasing the growth factor may increase efficiency and decrease complexity.

When the symbol is non punctured, or transmitted, results may be filtered. For example, the total number of hypotheses for an ML search may be 2ⁿ, and may be further constrained by a finite number of hypotheses (<<2ⁿ) for a tree search. Thus, order of transmitted symbols 425 and punctured symbols 415 may affect complexity.

In an example, puncturing 2 out of 4 symbols (k=2) may be completed according to two possible options. The first option may be puncturing the first two spines and the second option may be puncturing the third and fourth spines. In such as example, after filtering 82.5% of the hypotheses, the average number of total hypotheses is represented by Equation 4.

$${( {2}^{k} )}^{\# Spines} \cdot {( 1 - Filter \% )}^{\# Non - Punctured - Spines} = {( {2}^{2} )}^{4} \cdot {( 1 - 0.825 )}^{2} ≅ 7.84 \qquad ( 4 )$$

However, the distribution of the number of hypotheses for the first and second options is different. The difference in distribution of the two options leads to the complexity of the first option to be much higher than the second. By concentrating the puncturing towards the end of the puncturing scheme in the first option, the complexity is increased. As the complexity of the second option is higher, a limit to the number of hypotheses may lead to the discard of hypotheses, causing performance degradation. Thus, the distribution of the punctured symbols 415 may affect complexity and performance degradation. Other examples of subpasses 410 are illustrated by subpasses 410-d, 410-e, 410-f, 410-f, 410-g, and 410-g.

A puncturing scheme that uniformly the punctured symbols 415 and prioritizes puncturing at the beginning of the tree may reduce complexity and result in a smaller tree size. Techniques described herein provide for such an improved spinal coding puncturing scheme, which may be described with reference to FIG. 5.

FIG. 5 shows an example of a puncturing scheme 500 that supports improved puncturing scheme for spinal codes in accordance with one or more aspects of the present disclosure. The puncturing scheme 500 may implement or be implemented by other FIGs. described herein. Subpass 510-a, subpass 510-b, subpass 515-a, and subpass 515-b include punctured symbols 520 and transmitted symbols 525, each corresponding to a symbol number 505. The subpass 510-b may be an improved puncturing scheme of the subpass 510-a, and the subpass 515-b may be an improved puncturing scheme of the subpass 515-a.

Subpass 510-a may be an example of the subpass 410-c as described with reference to FIG. 4. A growth factor may be defined by (2^{k})^{x}, where x is the number of consecutive punctured symbols and k is the number of punctured symbols 520. As there are three consecutive punctured symbols 520, the growth factor is 4096. Additionally, the average number of consecutive punctures is 1.6 (the total number of symbols divided by the punctured symbols 520), indicating that a more efficient option exists (e.g., 1.6 is about 2 consecutive punctures).

Subpass 510-b describes an improved puncturing scheme of the subpass 510-a, where the punctured symbols 520 are evenly distributed. The subpass 510-b has a pattern of: 2 consecutive punctured symbols 520, 1 transmitted symbol 525, 2 consecutive punctured symbols 520, 1 transmitted symbol 525, 1 consecutive punctured symbols 520, 1 transmitted symbol 525, etc. The greatest number of consecutive punctured symbols 520 is two, in contrast to the three consecutive punctured symbols 520 of the subpass 510-a. The reduction of consecutive punctured symbols 520 may reduce complexity.

The subpass 515-a may be an example of the subpass 410-f as described with reference to FIG. 4. In subpass 515-a, 24 of the 32 symbols are transmitted symbols 525, and the last punctured symbol 520 is at the end of the tree, at symbol 31. The first punctured symbol 520 is symbol 3. The average number of spines between punctures is 4 (the number of spines divided by the number of punctured symbols). An option is available that decreases complexity.

Subpass 515-b describes an improved puncturing scheme of the subpass 515-a. The subpass 515-b prioritizes puncturing the beginning of the tree and transmitting the end of the tree. In contrast to subpass 515-a, the subpass 515-b punctures the first symbol, with three consecutive transmitted symbols 525 between each punctured symbol 520.

The puncturing scheme or algorithm may be predetermined, or may be signaled. For example, there may be several puncturing schemes that the encoder (e.g., network entity) may select from. The puncturing schemes may be mandatory, or may not be mandatory. In some examples, the puncture scheme will be adaptive, and the network entity may signal the puncturing scheme to the UE. For example, the puncturing may be signaled as part of an RRC configuration, or be dynamically updated by a medium access control control element (MAC-CE).

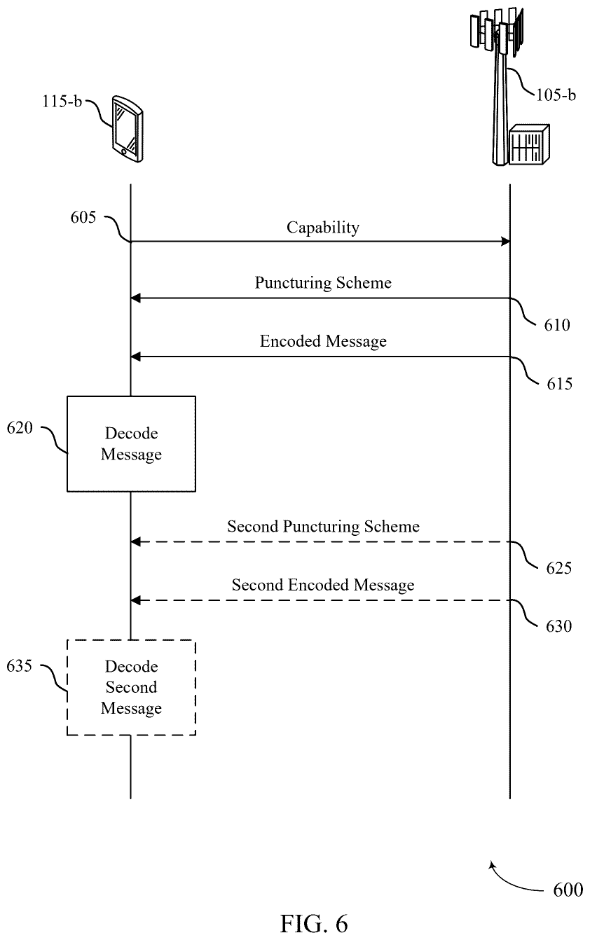

FIG. 6 shows an example of a process flow diagram 600 that supports improved puncturing scheme for spinal codes in accordance with one or more aspects of the present disclosure. The process flow diagram 600 describes the communications between a UE 115-b and a network entity 105-b, which may be examples of the UE 115 and the network entity 105 as described with reference to FIG. 1 and FIG. 2. The process flow diagram 600 may implement or be implemented by other figures described herein.

The operations between the UE 115-b and the network entity 105-b may be performed in different orders or at different times. Some operations may also be left out of the process flow diagram 600, or other operations may be added. Although the UE 115-b and the network entity 105-b are shown performing the operations of the process flow diagram 600, some aspects of some operations may also be performed by one or more other wireless devices.

At 605, the UE 115-b may transmit an indication of the capability of the UE 115-b to decode the message according to one or more puncturing schemes for the spinal coding scheme, where the indication of the puncturing scheme for the spinal coding scheme may be based on the capability of the UE 115-b.

At 610, the UE 115-b may receive, from the network entity 105-b, an indication of a puncturing scheme for a spinal coding scheme based on a capability of the UE 115-b, where the puncturing scheme indicates a puncturing distribution for one or more symbols of one or more spines of the spinal coding scheme. In some examples, the UE 115-b may receive the indication of the puncturing scheme for the spinal coding scheme by receiving one of an RRC message or a MAC-CE indicating the puncturing scheme.

At 615, the UE 115-b may receive, and the network entity 105-b may output, a message encoded according to the spinal coding scheme associated with the puncturing scheme. The message may be encoded by the network entity 105-b according to the spinal coding scheme to indicate one or more message segments corresponding to the one or more symbols and to the one or more spines based on the puncturing distribution of the puncturing scheme.

At 620, the UE 115-b may decode the message encoded according to the spinal coding scheme to obtain one or more message segments corresponding to the one or more symbols and to the one or more spines based on the puncturing distribution of the puncturing scheme.

Decoding the message may include puncturing the one or more symbols of the one or more spines of the spinal coding scheme based on a uniform puncturing distribution indicated by the puncturing distribution. In some examples, decoding the message may include puncturing the one or more symbols of the one or more spines of the spinal coding scheme based on a puncturing prioritization associated with the puncturing distribution.

In some examples, the puncturing prioritization may include prioritization of at least one symbol associated with the beginning of the one or more spines. In some examples, the puncturing distribution may be based on an average number of consecutive punctured symbols, an average number of spines of the spinal coding scheme, a growth factor associated with one or more puncturing locations, or a combination thereof.

At 625, the UE 115-b may receive, and the network entity 105-b may output, based on the capability of the UE 115-b, an indication of a second puncturing scheme for the spinal coding scheme that is different from the puncturing scheme.

At 630, the UE 115-b may receive a second message encoded according to the spinal coding scheme in accordance with the second puncturing scheme. The second encoded message may be encoded and output by the network entity 105-b. The network entity 105-b may encode a second message according to the spinal coding scheme based on a second puncturing distribution of the second puncturing scheme

At 635, the UE 115-b may decode the second message according to the spinal coding scheme based on the puncturing distribution of the second puncturing scheme.

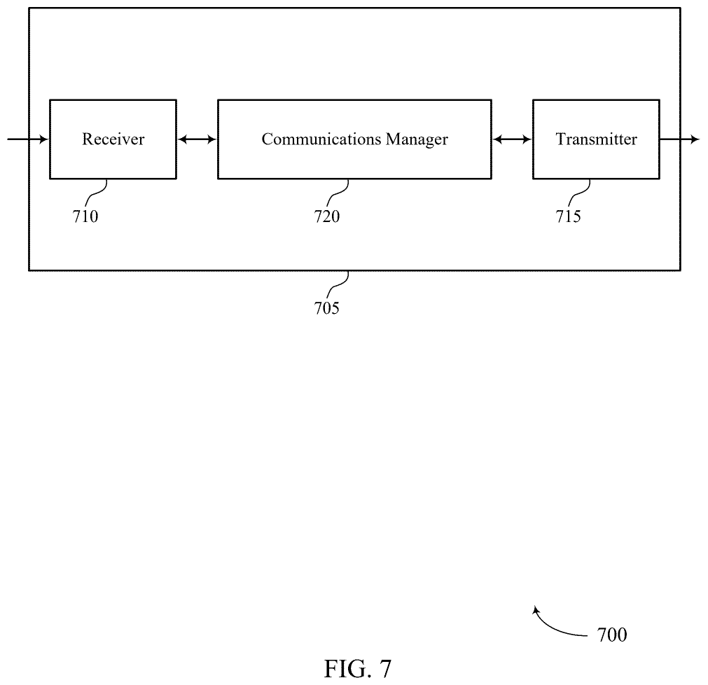

FIG. 7 shows a block diagram 700 of a device 705 that supports improved puncturing scheme for spinal codes in accordance with one or more aspects of the present disclosure. The device 705 may be an example of aspects of a UE 115 as described herein. The device 705 may include a receiver 710, a transmitter 715, and a communications manager 720. The device 705, or one or more components of the device 705 (e.g., the receiver 710, the transmitter 715, the communications manager 720), may include at least one processor, which may be coupled with at least one memory, to, individually or collectively, support or enable the described techniques. Each of these components may be in communication with one another (e.g., via one or more buses).

The receiver 710 may provide a means for receiving information such as packets, user data, control information, or any combination thereof associated with various information channels (e.g., control channels, data channels, information channels related to improved puncturing scheme for spinal codes). Information may be passed on to other components of the device 705. The receiver 710 may utilize a single antenna or a set of multiple antennas.

The transmitter 715 may provide a means for transmitting signals generated by other components of the device 705. For example, the transmitter 715 may transmit information such as packets, user data, control information, or any combination thereof associated with various information channels (e.g., control channels, data channels, information channels related to improved puncturing scheme for spinal codes). In some examples, the transmitter 715 may be co-located with a receiver 710 in a transceiver module. The transmitter 715 may utilize a single antenna or a set of multiple antennas.

The communications manager 720, the receiver 710, the transmitter 715, or various combinations or components thereof may be examples of means for performing various aspects of improved puncturing scheme for spinal codes as described herein. For example, the communications manager 720, the receiver 710, the transmitter 715, or various combinations or components thereof may be capable of performing one or more of the functions described herein.

In some examples, the communications manager 720, the receiver 710, the transmitter 715, or various combinations or components thereof may be implemented in hardware (e.g., in communications management circuitry). The hardware may include at least one of a processor, a digital signal processor (DSP), a central processing unit (CPU), an application-specific integrated circuit (ASIC), a field-programmable gate array (FPGA) or other programmable logic device, a microcontroller, discrete gate or transistor logic, discrete hardware components, or any combination thereof configured as or otherwise supporting, individually or collectively, a means for performing the functions described in the present disclosure. In some examples, at least one processor and at least one memory coupled with the at least one processor may be configured to perform one or more of the functions described herein (e.g., by one or more processors, individually or collectively, executing instructions stored in the at least one memory).

Additionally, or alternatively, the communications manager 720, the receiver 710, the transmitter 715, or various combinations or components thereof may be implemented in code (e.g., as communications management software or firmware) executed by at least one processor (e.g., referred to as a processor-executable code). If implemented in code executed by at least one processor, the functions of the communications manager 720, the receiver 710, the transmitter 715, or various combinations or components thereof may be performed by a general-purpose processor, a DSP, a CPU, an ASIC, an FPGA, a microcontroller, or any combination of these or other programmable logic devices (e.g., configured as or otherwise supporting, individually or collectively, a means for performing the functions described in the present disclosure).

In some examples, the communications manager 720 may be configured to perform various operations (e.g., receiving, obtaining, monitoring, outputting, transmitting) using or otherwise in cooperation with the receiver 710, the transmitter 715, or both. For example, the communications manager 720 may receive information from the receiver 710, send information to the transmitter 715, or be integrated in combination with the receiver 710, the transmitter 715, or both to obtain information, output information, or perform various other operations as described herein.

The communications manager 720 may support wireless communications in accordance with examples as disclosed herein. For example, the communications manager 720 is capable of, configured to, or operable to support a means for receiving, from a network entity, an indication of a puncturing scheme for a spinal coding scheme based on a capability of the UE, where the puncturing scheme indicates a puncturing distribution for one or more symbols of one or more spines of the spinal coding scheme. The communications manager 720 is capable of, configured to, or operable to support a means for receiving, from the network entity, a message encoded according to the spinal coding scheme associated with the puncturing scheme. The communications manager 720 is capable of, configured to, or operable to support a means for decoding the message encoded according to the spinal coding scheme to obtain one or more message segments corresponding to the one or more symbols and to the one or more spines based on the puncturing distribution of the puncturing scheme.

By including or configuring the communications manager 720 in accordance with examples as described herein, the device 705 (e.g., at least one processor controlling or otherwise coupled with the receiver 710, the transmitter 715, the communications manager 720, or a combination thereof) may support techniques for an improved puncturing scheme, which may result in various advantages, including reduced processing, reduced power consumption, more efficient utilization of communication resources, etc.

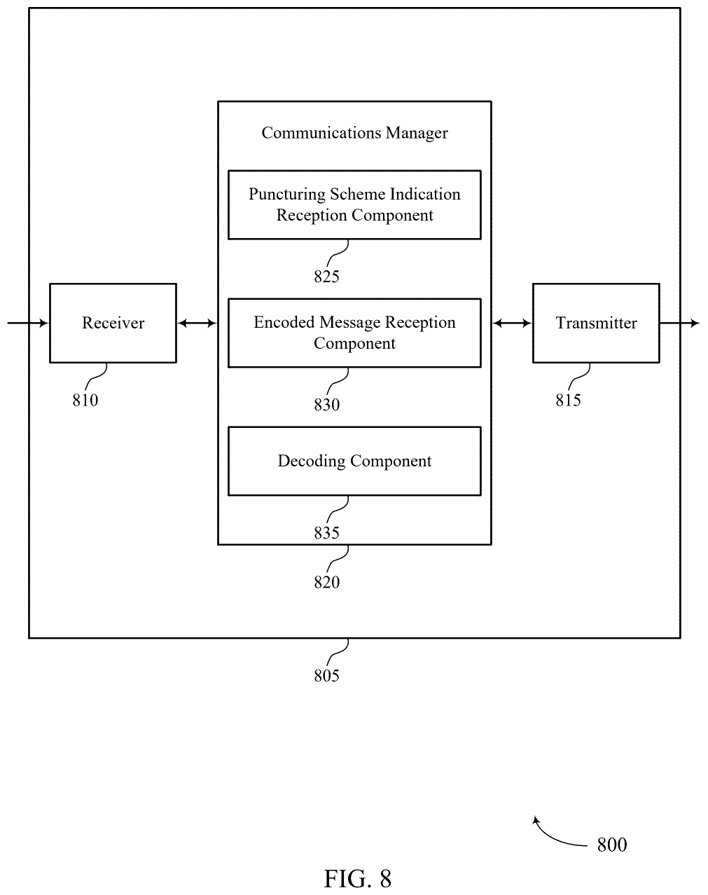

FIG. 8 shows a block diagram 800 of a device 805 that supports improved puncturing scheme for spinal codes in accordance with one or more aspects of the present disclosure. The device 805 may be an example of aspects of a device 705 or a UE 115 as described herein. The device 805 may include a receiver 810, a transmitter 815, and a communications manager 820. The device 805, or one or more components of the device 805 (e.g., the receiver 810, the transmitter 815, the communications manager 820), may include at least one processor, which may be coupled with at least one memory, to support the described techniques. Each of these components may be in communication with one another (e.g., via one or more buses).

The receiver 810 may provide a means for receiving information such as packets, user data, control information, or any combination thereof associated with various information channels (e.g., control channels, data channels, information channels related to improved puncturing scheme for spinal codes). Information may be passed on to other components of the device 805. The receiver 810 may utilize a single antenna or a set of multiple antennas.

The transmitter 815 may provide a means for transmitting signals generated by other components of the device 805. For example, the transmitter 815 may transmit information such as packets, user data, control information, or any combination thereof associated with various information channels (e.g., control channels, data channels, information channels related to improved puncturing scheme for spinal codes). In some examples, the transmitter 815 may be co-located with a receiver 810 in a transceiver module. The transmitter 815 may utilize a single antenna or a set of multiple antennas.

The device 805, or various components thereof, may be an example of means for performing various aspects of improved puncturing scheme for spinal codes as described herein. For example, the communications manager 820 may include a puncturing scheme indication reception component 825, an encoded message reception component 830, a decoding component 835, or any combination thereof. The communications manager 820 may be an example of aspects of a communications manager 720 as described herein. In some examples, the communications manager 820, or various components thereof, may be configured to perform various operations (e.g., receiving, obtaining, monitoring, outputting, transmitting) using or otherwise in cooperation with the receiver 810, the transmitter 815, or both. For example, the communications manager 820 may receive information from the receiver 810, send information to the transmitter 815, or be integrated in combination with the receiver 810, the transmitter 815, or both to obtain information, output information, or perform various other operations as described herein.

The communications manager 820 may support wireless communications in accordance with examples as disclosed herein. The puncturing scheme indication reception component 825 is capable of, configured to, or operable to support a means for receiving, from a network entity, an indication of a puncturing scheme for a spinal coding scheme based on a capability of the UE, where the puncturing scheme indicates a puncturing distribution for one or more symbols of one or more spines of the spinal coding scheme. The encoded message reception component 830 is capable of, configured to, or operable to support a means for receiving, from the network entity, a message encoded according to the spinal coding scheme associated with the puncturing scheme. The decoding component 835 is capable of, configured to, or operable to support a means for decoding the message encoded according to the spinal coding scheme to obtain one or more message segments corresponding to the one or more symbols and to the one or more spines based on the puncturing distribution of the puncturing scheme.

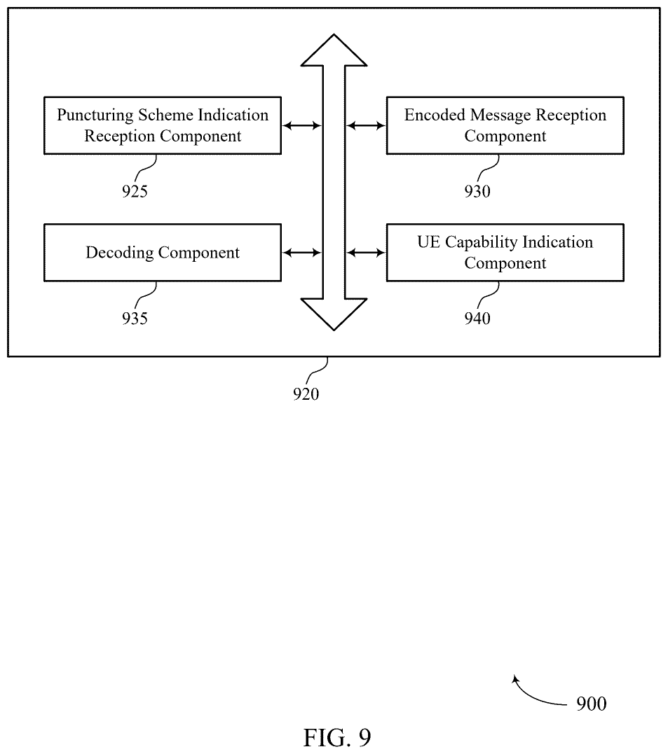

FIG. 9 shows a block diagram 900 of a communications manager 920 that supports improved puncturing scheme for spinal codes in accordance with one or more aspects of the present disclosure. The communications manager 920 may be an example of aspects of a communications manager 720, a communications manager 820, or both, as described herein. The communications manager 920, or various components thereof, may be an example of means for performing various aspects of improved puncturing scheme for spinal codes as described herein. For example, the communications manager 920 may include a puncturing scheme indication reception component 925, an encoded message reception component 930, a decoding component 935, a UE capability indication component 940, or any combination thereof. Each of these components, or components or subcomponents thereof (e.g., one or more processors, one or more memories), may communicate, directly or indirectly, with one another (e.g., via one or more buses).

The communications manager 920 may support wireless communications in accordance with examples as disclosed herein. The puncturing scheme indication reception component 925 is capable of, configured to, or operable to support a means for receiving, from a network entity, an indication of a puncturing scheme for a spinal coding scheme based on a capability of the UE, where the puncturing scheme indicates a puncturing distribution for one or more symbols of one or more spines of the spinal coding scheme. The encoded message reception component 930 is capable of, configured to, or operable to support a means for receiving, from the network entity, a message encoded according to the spinal coding scheme associated with the puncturing scheme. The decoding component 935 is capable of, configured to, or operable to support a means for decoding the message encoded according to the spinal coding scheme to obtain one or more message segments corresponding to the one or more symbols and to the one or more spines based on the puncturing distribution of the puncturing scheme.

In some examples, the UE capability indication component 940 is capable of, configured to, or operable to support a means for transmitting an indication of the capability of the UE to decode the message according to one or more puncturing schemes for the spinal coding scheme, where the indication of the puncturing scheme for the spinal coding scheme is based on the capability of the UE.

In some examples, the puncturing scheme indication reception component 925 is capable of, configured to, or operable to support a means for receiving, based on the capability of the UE, an indication of a second puncturing scheme for the spinal coding scheme different from the puncturing scheme. In some examples, the encoded message reception component 930 is capable of, configured to, or operable to support a means for receiving a second message encoded according to the spinal coding scheme in accordance with the second puncturing scheme. In some examples, the decoding component 935 is capable of, configured to, or operable to support a means for decoding the second message according to the spinal coding scheme based on a second puncturing distribution of the second puncturing scheme.

In some examples, to support receiving the indication of the puncturing scheme for the spinal coding scheme, the puncturing scheme indication reception component 925 is capable of, configured to, or operable to support a means for receiving one of a radio resource control message or a MAC-CE indicating the puncturing scheme.

In some examples, to support decoding the message, the decoding component 935 is capable of, configured to, or operable to support a means for puncturing the one or more symbols of the one or more spines of the spinal coding scheme based on a uniform puncturing distribution indicated by the puncturing distribution.

In some examples, to support decoding the message, the decoding component 935 is capable of, configured to, or operable to support a means for puncturing the one or more symbols of the one or more spines of the spinal coding scheme based on a puncturing prioritization associated with the puncturing distribution.

In some examples, the puncturing prioritization includes a prioritization of at least one symbol associated with the beginning of the one or more spines. In some examples, the puncturing distribution is based on an average number of consecutive punctured symbols, an average number of spines of the spinal coding scheme, a growth factor associated with one or more puncturing locations, or a combination thereof.

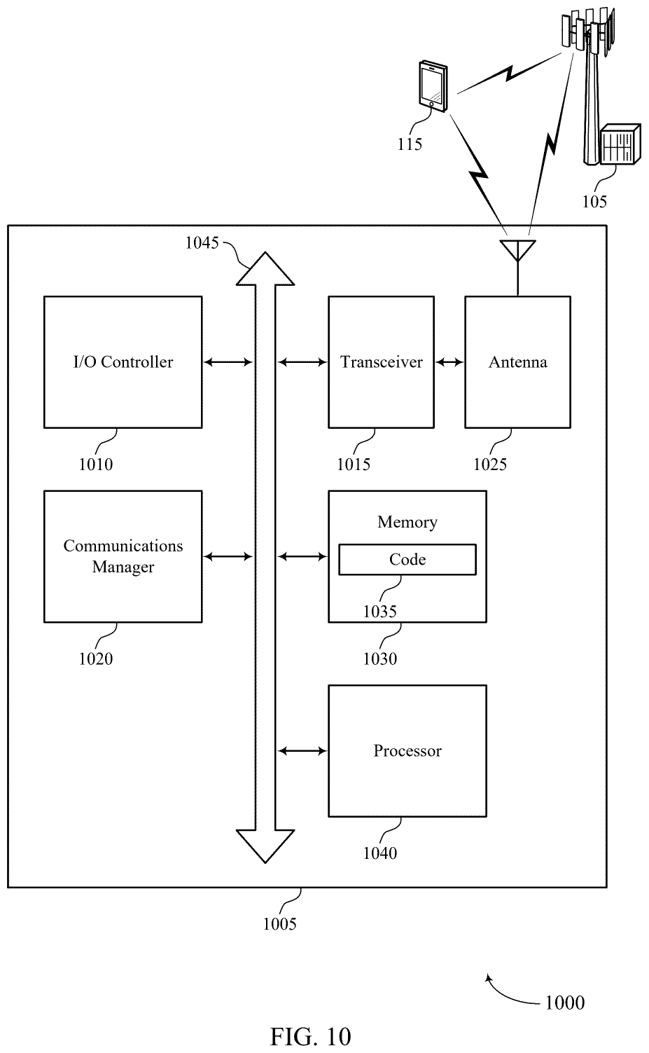

FIG. 10 shows a diagram of a system 1000 including a device 1005 that supports improved puncturing scheme for spinal codes in accordance with one or more aspects of the present disclosure. The device 1005 may be an example of or include components of a device 705, a device 805, or a UE 115 as described herein. The device 1005 may communicate (e.g., wirelessly) with one or more other devices (e.g., network entities 105, UEs 115, or a combination thereof). The device 1005 may include components for bi-directional voice and data communications including components for transmitting and receiving communications, such as a communications manager 1020, an input/output (I/O) controller, such as an I/O controller 1010, a transceiver 1015, one or more antennas 1025, at least one memory 1030, code 1035, and at least one processor 1040. These components may be in electronic communication or otherwise coupled (e.g., operatively, communicatively, functionally, electronically, electrically) via one or more buses (e.g., a bus 1045).

The I/O controller 1010 may manage input and output signals for the device 1005. The I/O controller 1010 may also manage peripherals not integrated into the device 1005. In some cases, the I/O controller 1010 may represent a physical connection or port to an external peripheral. In some cases, the I/O controller 1010 may utilize an operating system such as iOS®, ANDROID®, MS-DOS®, MS-WINDOWS®, OS/2®, UNIX®, LINUX®, or another known operating system. Additionally, or alternatively, the I/O controller 1010 may represent or interact with a modem, a keyboard, a mouse, a touchscreen, or a similar device. In some cases, the I/O controller 1010 may be implemented as part of one or more processors, such as the at least one processor 1040. In some cases, a user may interact with the device 1005 via the I/O controller 1010 or via hardware components controlled by the I/O controller 1010.

In some cases, the device 1005 may include a single antenna. However, in some other cases, the device 1005 may have more than one antenna, which may be capable of concurrently transmitting or receiving multiple wireless transmissions. The transceiver 1015 may communicate bi-directionally via the one or more antennas 1025 using wired or wireless links as described herein. For example, the transceiver 1015 may represent a wireless transceiver and may communicate bi-directionally with another wireless transceiver. The transceiver 1015 may also include a modem to modulate the packets, to provide the modulated packets to one or more antennas 1025 for transmission, and to demodulate packets received from the one or more antennas 1025. The transceiver 1015, or the transceiver 1015 and one or more antennas 1025, may be an example of a transmitter 715, a transmitter 815, a receiver 710, a receiver 810, or any combination thereof or component thereof, as described herein.

The at least one memory 1030 may include random access memory (RAM) and read-only memory (ROM). The at least one memory 1030 may store computer-readable, computer-executable, or processor-executable code, such as the code 1035. The code 1035 may include instructions that, when executed by the at least one processor 1040, cause the device 1005 to perform various functions described herein. The code 1035 may be stored in a non-transitory computer-readable medium such as system memory or another type of memory. In some cases, the code 1035 may not be directly executable by the at least one processor 1040 but may cause a computer (e.g., when compiled and executed) to perform functions described herein. In some cases, the at least one memory 1030 may include, among other things, a basic I/O system (BIOS) which may control basic hardware or software operation such as the interaction with peripheral components or devices.

The at least one processor 1040 may include one or more intelligent hardware devices (e.g., one or more general-purpose processors, one or more DSPs, one or more CPUs, one or more graphics processing units (GPUs), one or more neural processing units (NPUs) (also referred to as neural network processors or deep learning processors (DLPs)), one or more microcontrollers, one or more ASICs, one or more FPGAs, one or more programmable logic devices, discrete gate or transistor logic, one or more discrete hardware components, or any combination thereof). In some cases, the at least one processor 1040 may be configured to operate a memory array using a memory controller. In some other cases, a memory controller may be integrated into the at least one processor 1040. The at least one processor 1040 may be configured to execute computer-readable instructions stored in a memory (e.g., the at least one memory 1030) to cause the device 1005 to perform various functions (e.g., functions or tasks supporting improved puncturing scheme for spinal codes). For example, the device 1005 or a component of the device 1005 may include at least one processor 1040 and at least one memory 1030 coupled with or to the at least one processor 1040, the at least one processor 1040 and the at least one memory 1030 configured to perform various functions described herein.

In some examples, the at least one processor 1040 may include multiple processors and the at least one memory 1030 may include multiple memories. One or more of the multiple processors may be coupled with one or more of the multiple memories, which may, individually or collectively, be configured to perform various functions described herein. In some examples, the at least one processor 1040 may be a component of a processing system, which may refer to a system (such as a series) of machines, circuitry (including, for example, one or both of processor circuitry (which may include the at least one processor 1040) and memory circuitry (which may include the at least one memory 1030)), or components, that receives or obtains inputs and processes the inputs to produce, generate, or obtain a set of outputs. The processing system may be configured to perform one or more of the functions described herein. For example, the at least one processor 1040 or a processing system including the at least one processor 1040 may be configured to, configurable to, or operable to cause the device 1005 to perform one or more of the functions described herein. Further, as described herein, being “configured to,” being “configurable to,” and being “operable to” may be used interchangeably and may be associated with a capability, when executing code 1035 (e.g., processor-executable code) stored in the at least one memory 1030 or otherwise, to perform one or more of the functions described herein.

The communications manager 1020 may support wireless communications in accordance with examples as disclosed herein. For example, the communications manager 1020 is capable of, configured to, or operable to support a means for receiving, from a network entity, an indication of a puncturing scheme for a spinal coding scheme based on a capability of the UE, where the puncturing scheme indicates a puncturing distribution for one or more symbols of one or more spines of the spinal coding scheme. The communications manager 1020 is capable of, configured to, or operable to support a means for receiving, from the network entity, a message encoded according to the spinal coding scheme associated with the puncturing scheme. The communications manager 1020 is capable of, configured to, or operable to support a means for decoding the message encoded according to the spinal coding scheme to obtain one or more message segments corresponding to the one or more symbols and to the one or more spines based on the puncturing distribution of the puncturing scheme.

By including or configuring the communications manager 1020 in accordance with examples as described herein, the device 1005 may support techniques for an improved puncturing scheme, which may result in various advantages, including improved communication reliability, reduced latency, improved user experience related to reduced processing, reduced power consumption, more efficient utilization of communication resources, improved coordination between devices, longer battery life, improved utilization of processing capability, etc.

In some examples, the communications manager 1020 may be configured to perform various operations (e.g., receiving, monitoring, transmitting) using or otherwise in cooperation with the transceiver 1015, the one or more antennas 1025, or any combination thereof. Although the communications manager 1020 is illustrated as a separate component, in some examples, one or more functions described with reference to the communications manager 1020 may be supported by or performed by the at least one processor 1040, the at least one memory 1030, the code 1035, or any combination thereof. For example, the code 1035 may include instructions executable by the at least one processor 1040 to cause the device 1005 to perform various aspects of improved puncturing scheme for spinal codes as described herein, or the at least one processor 1040 and the at least one memory 1030 may be otherwise configured to, individually or collectively, perform or support such operations.

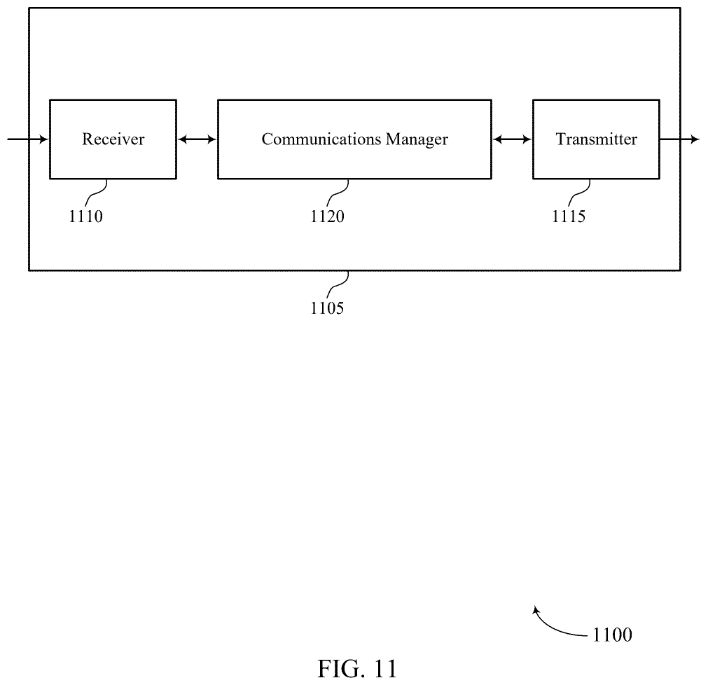

FIG. 11 shows a block diagram 1100 of a device 1105 that supports improved puncturing scheme for spinal codes in accordance with one or more aspects of the present disclosure. The device 1105 may be an example of aspects of a network entity 105 as described herein. The device 1105 may include a receiver 1110, a transmitter 1115, and a communications manager 1120. The device 1105, or one or more components of the device 1105 (e.g., the receiver 1110, the transmitter 1115, the communications manager 1120), may include at least one processor, which may be coupled with at least one memory, to, individually or collectively, support or enable the described techniques. Each of these components may be in communication with one another (e.g., via one or more buses).

The receiver 1110 may provide a means for obtaining (e.g., receiving, determining, identifying) information such as user data, control information, or any combination thereof (e.g., I/Q samples, symbols, packets, protocol data units, service data units) associated with various channels (e.g., control channels, data channels, information channels, channels associated with a protocol stack). Information may be passed on to other components of the device 1105. In some examples, the receiver 1110 may support obtaining information by receiving signals via one or more antennas. Additionally, or alternatively, the receiver 1110 may support obtaining information by receiving signals via one or more wired (e.g., electrical, fiber optic) interfaces, wireless interfaces, or any combination thereof.

The transmitter 1115 may provide a means for outputting (e.g., transmitting, providing, conveying, sending) information generated by other components of the device 1105. For example, the transmitter 1115 may output information such as user data, control information, or any combination thereof (e.g., I/Q samples, symbols, packets, protocol data units, service data units) associated with various channels (e.g., control channels, data channels, information channels, channels associated with a protocol stack). In some examples, the transmitter 1115 may support outputting information by transmitting signals via one or more antennas. Additionally, or alternatively, the transmitter 1115 may support outputting information by transmitting signals via one or more wired (e.g., electrical, fiber optic) interfaces, wireless interfaces, or any combination thereof. In some examples, the transmitter 1115 and the receiver 1110 may be co-located in a transceiver, which may include or be coupled with a modem.

The communications manager 1120, the receiver 1110, the transmitter 1115, or various combinations or components thereof may be examples of means for performing various aspects of improved puncturing scheme for spinal codes as described herein. For example, the communications manager 1120, the receiver 1110, the transmitter 1115, or various combinations or components thereof may be capable of performing one or more of the functions described herein.

In some examples, the communications manager 1120, the receiver 1110, the transmitter 1115, or various combinations or components thereof may be implemented in hardware (e.g., in communications management circuitry). The hardware may include at least one of a processor, a DSP, a CPU, an ASIC, an FPGA or other programmable logic device, a microcontroller, discrete gate or transistor logic, discrete hardware components, or any combination thereof configured as or otherwise supporting, individually or collectively, a means for performing the functions described in the present disclosure. In some examples, at least one processor and at least one memory coupled with the at least one processor may be configured to perform one or more of the functions described herein (e.g., by one or more processors, individually or collectively, executing instructions stored in the at least one memory).

Additionally, or alternatively, the communications manager 1120, the receiver 1110, the transmitter 1115, or various combinations or components thereof may be implemented in code (e.g., as communications management software or firmware) executed by at least one processor (e.g., referred to as a processor-executable code). If implemented in code executed by at least one processor, the functions of the communications manager 1120, the receiver 1110, the transmitter 1115, or various combinations or components thereof may be performed by a general-purpose processor, a DSP, a CPU, an ASIC, an FPGA, a microcontroller, or any combination of these or other programmable logic devices (e.g., configured as or otherwise supporting, individually or collectively, a means for performing the functions described in the present disclosure).

In some examples, the communications manager 1120 may be configured to perform various operations (e.g., receiving, obtaining, monitoring, outputting, transmitting) using or otherwise in cooperation with the receiver 1110, the transmitter 1115, or both. For example, the communications manager 1120 may receive information from the receiver 1110, send information to the transmitter 1115, or be integrated in combination with the receiver 1110, the transmitter 1115, or both to obtain information, output information, or perform various other operations as described herein.

The communications manager 1120 may support wireless communications in accordance with examples as disclosed herein. For example, the communications manager 1120 is capable of, configured to, or operable to support a means for outputting, to a UE, an indication of a puncturing scheme for a spinal coding scheme, where the puncturing scheme indicates a puncturing distribution for one or more symbols of one or more spines of the spinal coding scheme. The communications manager 1120 is capable of, configured to, or operable to support a means for encoding a message according to the spinal coding scheme to indicate one or more message segments corresponding to the one or more symbols and to the one or more spines based on the puncturing distribution of the puncturing scheme. The communications manager 1120 is capable of, configured to, or operable to support a means for outputting, to the UE, the message encoded according to the spinal coding scheme associated with the puncturing scheme.

By including or configuring the communications manager 1120 in accordance with examples as described herein, the device 1105 (e.g., at least one processor controlling or otherwise coupled with the receiver 1110, the transmitter 1115, the communications manager 1120, or a combination thereof) may support techniques for an improved puncturing scheme, which may result in various advantages, including reduced processing, reduced power consumption, more efficient utilization of communication resources, etc.

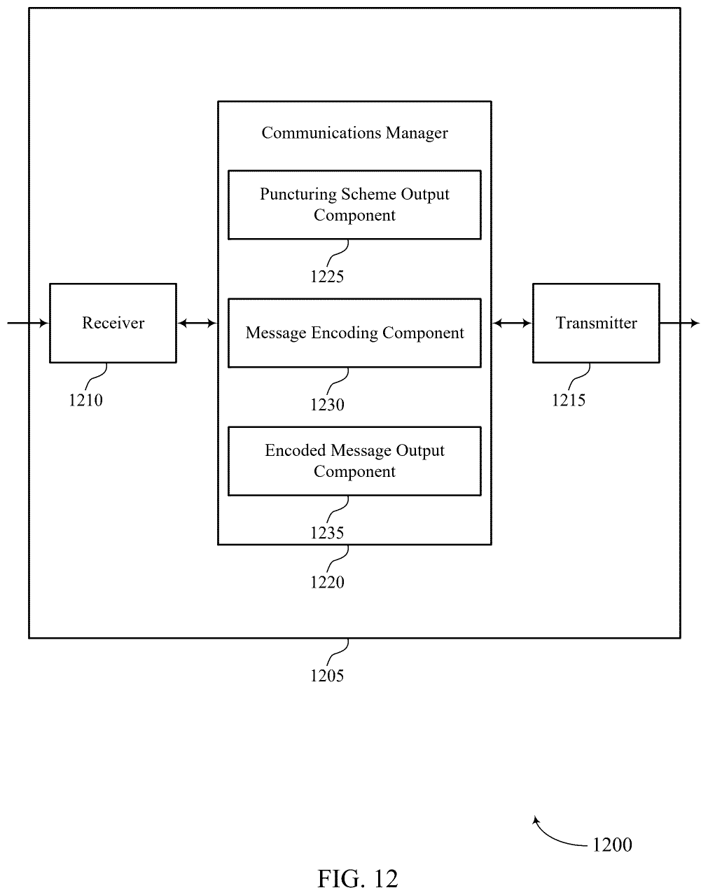

FIG. 12 shows a block diagram 1200 of a device 1205 that supports improved puncturing scheme for spinal codes in accordance with one or more aspects of the present disclosure. The device 1205 may be an example of aspects of a device 1105 or a network entity 105 as described herein. The device 1205 may include a receiver 1210, a transmitter 1215, and a communications manager 1220. The device 1205, or one or more components of the device 1205 (e.g., the receiver 1210, the transmitter 1215, the communications manager 1220), may include at least one processor, which may be coupled with at least one memory, to support the described techniques. Each of these components may be in communication with one another (e.g., via one or more buses).

The receiver 1210 may provide a means for obtaining (e.g., receiving, determining, identifying) information such as user data, control information, or any combination thereof (e.g., I/Q samples, symbols, packets, protocol data units, service data units) associated with various channels (e.g., control channels, data channels, information channels, channels associated with a protocol stack). Information may be passed on to other components of the device 1205. In some examples, the receiver 1210 may support obtaining information by receiving signals via one or more antennas. Additionally, or alternatively, the receiver 1210 may support obtaining information by receiving signals via one or more wired (e.g., electrical, fiber optic) interfaces, wireless interfaces, or any combination thereof.

The transmitter 1215 may provide a means for outputting (e.g., transmitting, providing, conveying, sending) information generated by other components of the device 1205. For example, the transmitter 1215 may output information such as user data, control information, or any combination thereof (e.g., I/Q samples, symbols, packets, protocol data units, service data units) associated with various channels (e.g., control channels, data channels, information channels, channels associated with a protocol stack). In some examples, the transmitter 1215 may support outputting information by transmitting signals via one or more antennas. Additionally, or alternatively, the transmitter 1215 may support outputting information by transmitting signals via one or more wired (e.g., electrical, fiber optic) interfaces, wireless interfaces, or any combination thereof. In some examples, the transmitter 1215 and the receiver 1210 may be co-located in a transceiver, which may include or be coupled with a modem.

The device 1205, or various components thereof, may be an example of means for performing various aspects of improved puncturing scheme for spinal codes as described herein. For example, the communications manager 1220 may include a puncturing scheme output component 1225, a message encoding component 1230, an encoded message output component 1235, or any combination thereof. The communications manager 1220 may be an example of aspects of a communications manager 1120 as described herein. In some examples, the communications manager 1220, or various components thereof, may be configured to perform various operations (e.g., receiving, obtaining, monitoring, outputting, transmitting) using or otherwise in cooperation with the receiver 1210, the transmitter 1215, or both. For example, the communications manager 1220 may receive information from the receiver 1210, send information to the transmitter 1215, or be integrated in combination with the receiver 1210, the transmitter 1215, or both to obtain information, output information, or perform various other operations as described herein.

The communications manager 1220 may support wireless communications in accordance with examples as disclosed herein. The puncturing scheme output component 1225 is capable of, configured to, or operable to support a means for outputting, to a UE, an indication of a puncturing scheme for a spinal coding scheme, where the puncturing scheme indicates a puncturing distribution for one or more symbols of one or more spines of the spinal coding scheme. The message encoding component 1230 is capable of, configured to, or operable to support a means for encoding a message according to the spinal coding scheme to indicate one or more message segments corresponding to the one or more symbols and to the one or more spines based on the puncturing distribution of the puncturing scheme. The encoded message output component 1235 is capable of, configured to, or operable to support a means for outputting, to the UE, the message encoded according to the spinal coding scheme associated with the puncturing scheme.

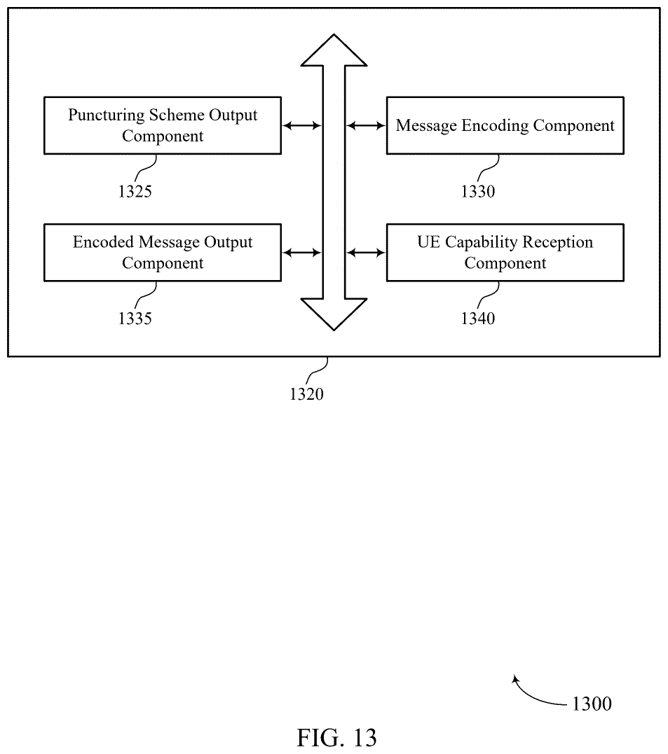

FIG. 13 shows a block diagram 1300 of a communications manager 1320 that supports improved puncturing scheme for spinal codes in accordance with one or more aspects of the present disclosure. The communications manager 1320 may be an example of aspects of a communications manager 1120, a communications manager 1220, or both, as described herein. The communications manager 1320, or various components thereof, may be an example of means for performing various aspects of improved puncturing scheme for spinal codes as described herein. For example, the communications manager 1320 may include a puncturing scheme output component 1325, a message encoding component 1330, an encoded message output component 1335, a UE capability reception component 1340, or any combination thereof. Each of these components, or components or subcomponents thereof (e.g., one or more processors, one or more memories), may communicate, directly or indirectly, with one another (e.g., via one or more buses). The communications may include communications within a protocol layer of a protocol stack, communications associated with a logical channel of a protocol stack (e.g., between protocol layers of a protocol stack, within a device, component, or virtualized component associated with a network entity 105, between devices, components, or virtualized components associated with a network entity 105), or any combination thereof.

The communications manager 1320 may support wireless communications in accordance with examples as disclosed herein. The puncturing scheme output component 1325 is capable of, configured to, or operable to support a means for outputting, to a UE, an indication of a puncturing scheme for a spinal coding scheme, where the puncturing scheme indicates a puncturing distribution for one or more symbols of one or more spines of the spinal coding scheme. The message encoding component 1330 is capable of, configured to, or operable to support a means for encoding a message according to the spinal coding scheme to indicate one or more message segments corresponding to the one or more symbols and to the one or more spines based on the puncturing distribution of the puncturing scheme. The encoded message output component 1335 is capable of, configured to, or operable to support a means for outputting, to the UE, the message encoded according to the spinal coding scheme associated with the puncturing scheme.

In some examples, the UE capability reception component 1340 is capable of, configured to, or operable to support a means for obtaining an indication of a capability of the UE to decode the message according to one or more puncturing schemes for the spinal coding scheme, where the indication of the puncturing scheme for the spinal coding scheme is based on the capability of the UE.

In some examples, the puncturing scheme output component 1325 is capable of, configured to, or operable to support a means for outputting, based on the capability of the UE, an indication of a second puncturing scheme for the spinal coding scheme different from the puncturing scheme. In some examples, the message encoding component 1330 is capable of, configured to, or operable to support a means for encoding a second message according to the spinal coding scheme based on a second puncturing distribution of the second puncturing scheme. In some examples, the encoded message output component 1335 is capable of, configured to, or operable to support a means for outputting the second message encoded according to the spinal coding scheme in accordance with the second puncturing scheme.

In some examples, to support outputting the indication of the puncturing scheme for the spinal coding scheme, the puncturing scheme output component 1325 is capable of, configured to, or operable to support a means for outputting one of a radio resource control message or a medium access control (MAC) control element (CE) indicating the puncturing scheme.

In some examples, the puncturing distribution is based on an average number of consecutive punctured symbols, an average number of spines of the spinal coding scheme, a growth factor associated with one or more puncturing locations, or a combination thereof.

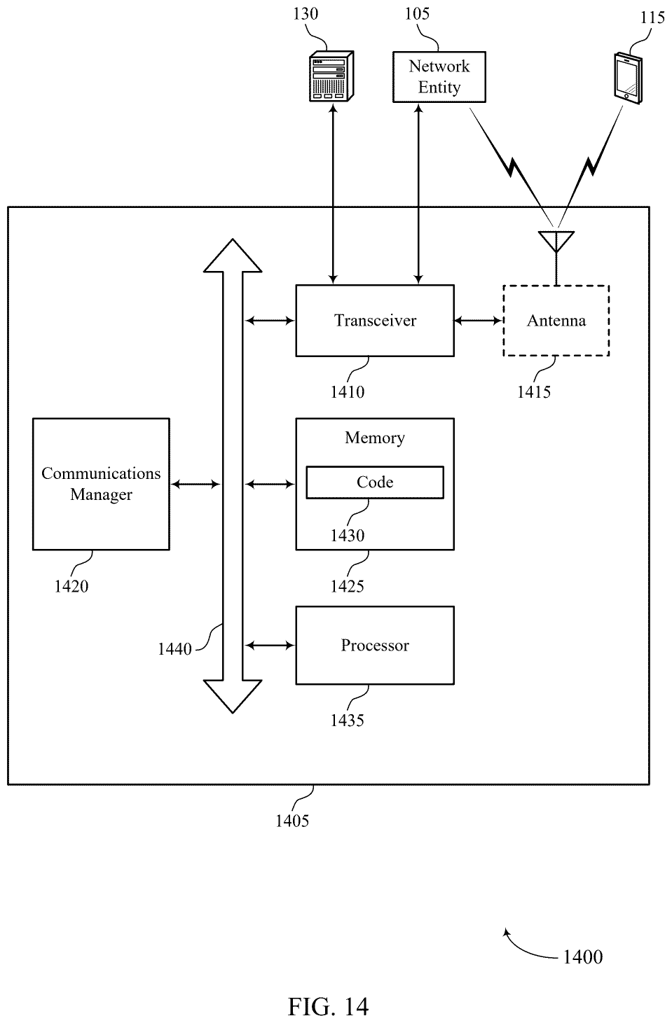

FIG. 14 shows a diagram of a system 1400 including a device 1405 that supports improved puncturing scheme for spinal codes in accordance with one or more aspects of the present disclosure. The device 1405 may be an example of or include components of a device 1105, a device 1205, or a network entity 105 as described herein. The device 1405 may communicate with other network devices or network equipment such as one or more of the network entities 105, UEs 115, or any combination thereof. The communications may include communications over one or more wired interfaces, over one or more wireless interfaces, or any combination thereof. The device 1405 may include components that support outputting and obtaining communications, such as a communications manager 1420, a transceiver 1410, one or more antennas 1415, at least one memory 1425, code 1430, and at least one processor 1435. These components may be in electronic communication or otherwise coupled (e.g., operatively, communicatively, functionally, electronically, electrically) via one or more buses (e.g., a bus 1440).

The transceiver 1410 may support bi-directional communications via wired links, wireless links, or both as described herein. In some examples, the transceiver 1410 may include a wired transceiver and may communicate bi-directionally with another wired transceiver. Additionally, or alternatively, in some examples, the transceiver 1410 may include a wireless transceiver and may communicate bi-directionally with another wireless transceiver. In some examples, the device 1405 may include one or more antennas 1415, which may be capable of transmitting or receiving wireless transmissions (e.g., concurrently). The transceiver 1410 may also include a modem to modulate signals, to provide the modulated signals for transmission (e.g., by one or more antennas 1415, by a wired transmitter), to receive modulated signals (e.g., from one or more antennas 1415, from a wired receiver), and to demodulate signals. In some implementations, the transceiver 1410 may include one or more interfaces, such as one or more interfaces coupled with the one or more antennas 1415 that are configured to support various receiving or obtaining operations, or one or more interfaces coupled with the one or more antennas 1415 that are configured to support various transmitting or outputting operations, or a combination thereof. In some implementations, the transceiver 1410 may include or be configured for coupling with one or more processors or one or more memory components that are operable to perform or support operations based on received or obtained information or signals, or to generate information or other signals for transmission or other outputting, or any combination thereof. In some implementations, the transceiver 1410, or the transceiver 1410 and the one or more antennas 1415, or the transceiver 1410 and the one or more antennas 1415 and one or more processors or one or more memory components (e.g., the at least one processor 1435, the at least one memory 1425, or both), may be included in a chip or chip assembly that is installed in the device 1405. In some examples, the transceiver 1410 may be operable to support communications via one or more communications links (e.g., communication link(s) 125, backhaul communication link(s) 120, a midhaul communication link 162, a fronthaul communication link 168).

The at least one memory 1425 may include RAM, ROM, or any combination thereof. The at least one memory 1425 may store computer-readable, computer-executable, or processor-executable code, such as the code 1430. The code 1430 may include instructions that, when executed by one or more of the at least one processor 1435, cause the device 1405 to perform various functions described herein. The code 1430 may be stored in a non-transitory computer-readable medium such as system memory or another type of memory. In some cases, the code 1430 may not be directly executable by a processor of the at least one processor 1435 but may cause a computer (e.g., when compiled and executed) to perform functions described herein. In some cases, the at least one memory 1425 may include, among other things, a BIOS which may control basic hardware or software operation such as the interaction with peripheral components or devices. In some examples, the at least one processor 1435 may include multiple processors and the at least one memory 1425 may include multiple memories. One or more of the multiple processors may be coupled with one or more of the multiple memories which may, individually or collectively, be configured to perform various functions herein (for example, as part of a processing system).

The at least one processor 1435 may include one or more intelligent hardware devices (e.g., one or more general-purpose processors, one or more DSPs, one or more CPUs, one or more graphics processing units (GPUs), one or more neural processing units (NPUs) (also referred to as neural network processors or deep learning processors (DLPs)), one or more microcontrollers, one or more ASICs, one or more FPGAs, one or more programmable logic devices, discrete gate or transistor logic, one or more discrete hardware components, or any combination thereof). In some cases, the at least one processor 1435 may be configured to operate a memory array using a memory controller. In some other cases, a memory controller may be integrated into one or more of the at least one processor 1435. The at least one processor 1435 may be configured to execute computer-readable instructions stored in a memory (e.g., one or more of the at least one memory 1425) to cause the device 1405 to perform various functions (e.g., functions or tasks supporting improved puncturing scheme for spinal codes). For example, the device 1405 or a component of the device 1405 may include at least one processor 1435 and at least one memory 1425 coupled with one or more of the at least one processor 1435, the at least one processor 1435 and the at least one memory 1425 configured to perform various functions described herein. The at least one processor 1435 may be an example of a cloud-computing platform (e.g., one or more physical nodes and supporting software such as operating systems, virtual machines, or container instances) that may host the functions (e.g., by executing code 1430) to perform the functions of the device 1405. The at least one processor 1435 may be any one or more suitable processors capable of executing scripts or instructions of one or more software programs stored in the device 1405 (such as within one or more of the at least one memory 1425).

In some examples, the at least one processor 1435 may include multiple processors and the at least one memory 1425 may include multiple memories. One or more of the multiple processors may be coupled with one or more of the multiple memories, which may, individually or collectively, be configured to perform various functions herein. In some examples, the at least one processor 1435 may be a component of a processing system, which may refer to a system (such as a series) of machines, circuitry (including, for example, one or both of processor circuitry (which may include the at least one processor 1435) and memory circuitry (which may include the at least one memory 1425)), or components, that receives or obtains inputs and processes the inputs to produce, generate, or obtain a set of outputs. The processing system may be configured to perform one or more of the functions described herein. For example, the at least one processor 1435 or a processing system including the at least one processor 1435 may be configured to, configurable to, or operable to cause the device 1405 to perform one or more of the functions described herein. Further, as described herein, being “configured to,” being “configurable to,” and being “operable to” may be used interchangeably and may be associated with a capability, when executing code stored in the at least one memory 1425 or otherwise, to perform one or more of the functions described herein.

In some examples, a bus 1440 may support communications of (e.g., within) a protocol layer of a protocol stack. In some examples, a bus 1440 may support communications associated with a logical channel of a protocol stack (e.g., between protocol layers of a protocol stack), which may include communications performed within a component of the device 1405, or between different components of the device 1405 that may be co-located or located in different locations (e.g., where the device 1405 may refer to a system in which one or more of the communications manager 1420, the transceiver 1410, the at least one memory 1425, the code 1430, and the at least one processor 1435 may be located in one of the different components or divided between different components).

In some examples, the communications manager 1420 may manage aspects of communications with a core network 130 (e.g., via one or more wired or wireless backhaul links). For example, the communications manager 1420 may manage the transfer of data communications for client devices, such as one or more UEs 115. In some examples, the communications manager 1420 may manage communications with one or more other network entities 105, and may include a controller or scheduler for controlling communications with UEs 115 (e.g., in cooperation with the one or more other network devices). In some examples, the communications manager 1420 may support an X2 interface within an LTE/LTE-A wireless communications network technology to provide communication between network entities 105.

The communications manager 1420 may support wireless communications in accordance with examples as disclosed herein. For example, the communications manager 1420 is capable of, configured to, or operable to support a means for outputting, to a UE, an indication of a puncturing scheme for a spinal coding scheme, where the puncturing scheme indicates a puncturing distribution for one or more symbols of one or more spines of the spinal coding scheme. The communications manager 1420 is capable of, configured to, or operable to support a means for encoding a message according to the spinal coding scheme to indicate one or more message segments corresponding to the one or more symbols and to the one or more spines based on the puncturing distribution of the puncturing scheme. The communications manager 1420 is capable of, configured to, or operable to support a means for outputting, to the UE, the message encoded according to the spinal coding scheme associated with the puncturing scheme.

By including or configuring the communications manager 1420 in accordance with examples as described herein, the device 1405 may support techniques for an improved puncturing scheme, which may result in various advantages, including improved communication reliability, reduced latency, improved user experience related to reduced processing, reduced power consumption, more efficient utilization of communication resources, improved coordination between devices, longer battery life, improved utilization of processing capability, etc.

In some examples, the communications manager 1420 may be configured to perform various operations (e.g., receiving, obtaining, monitoring, outputting, transmitting) using or otherwise in cooperation with the transceiver 1410, the one or more antennas 1415 (e.g., where applicable), or any combination thereof. Although the communications manager 1420 is illustrated as a separate component, in some examples, one or more functions described with reference to the communications manager 1420 may be supported by or performed by the transceiver 1410, one or more of the at least one processor 1435, one or more of the at least one memory 1425, the code 1430, or any combination thereof (for example, by a processing system including at least a portion of the at least one processor 1435, the at least one memory 1425, the code 1430, or any combination thereof). For example, the code 1430 may include instructions executable by one or more of the at least one processor 1435 to cause the device 1405 to perform various aspects of improved puncturing scheme for spinal codes as described herein, or the at least one processor 1435 and the at least one memory 1425 may be otherwise configured to, individually or collectively, perform or support such operations.

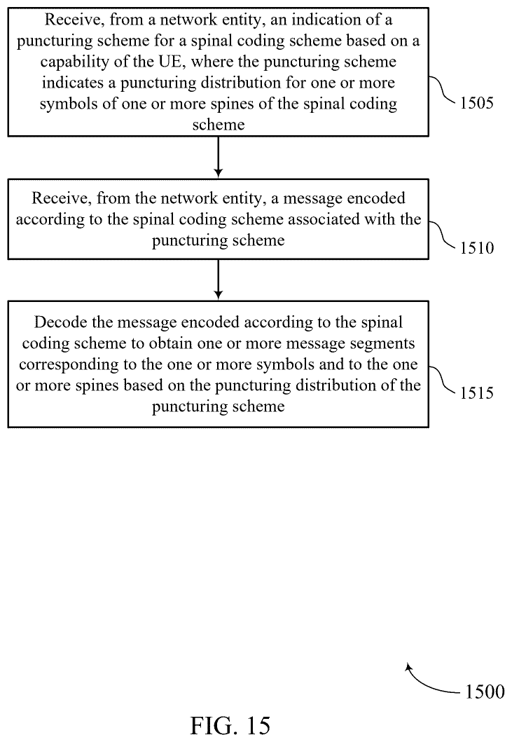

FIG. 15 shows a flowchart illustrating a method 1500 that supports improved puncturing scheme for spinal codes in accordance with one or more aspects of the present disclosure. The operations of the method 1500 may be implemented by a UE or its components as described herein. For example, the operations of the method 1500 may be performed by a UE 115 as described with reference to FIGS. 1 through 10. In some examples, a UE may execute a set of instructions to control the functional elements of the UE to perform the described functions. Additionally, or alternatively, the UE may perform aspects of the described functions using special-purpose hardware.

At 1505, the method may include receiving, from a network entity, an indication of a puncturing scheme for a spinal coding scheme based on a capability of the UE, where the puncturing scheme indicates a puncturing distribution for one or more symbols of one or more spines of the spinal coding scheme. The operations of 1505 may be performed in accordance with examples as disclosed herein. In some examples, aspects of the operations of 1505 may be performed by a puncturing scheme indication reception component 925 as described with reference to FIG. 9.

At 1510, the method may include receiving, from the network entity, a message encoded according to the spinal coding scheme associated with the puncturing scheme. The operations of 1510 may be performed in accordance with examples as disclosed herein. In some examples, aspects of the operations of 1510 may be performed by an encoded message reception component 930 as described with reference to FIG. 9.

At 1515, the method may include decoding the message encoded according to the spinal coding scheme to obtain one or more message segments corresponding to the one or more symbols and to the one or more spines based on the puncturing distribution of the puncturing scheme. The operations of 1515 may be performed in accordance with examples as disclosed herein. In some examples, aspects of the operations of 1515 may be performed by a decoding component 935 as described with reference to FIG. 9.

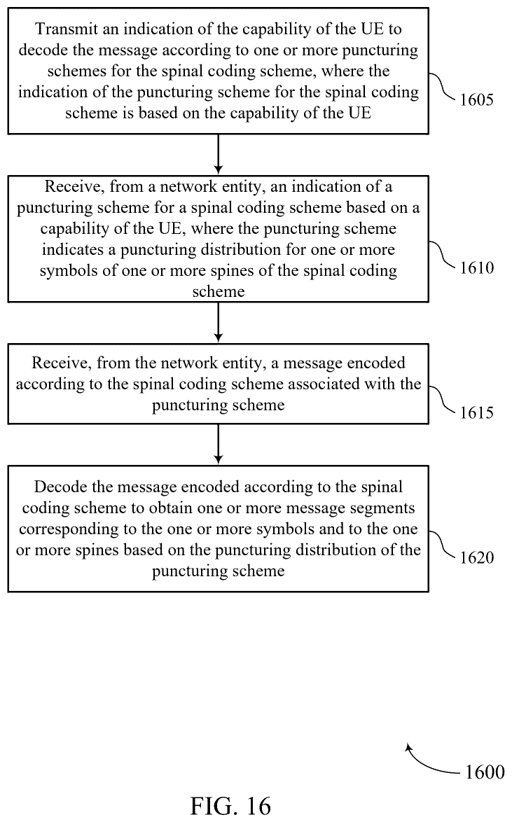

FIG. 16 shows a flowchart illustrating a method 1600 that supports improved puncturing scheme for spinal codes in accordance with one or more aspects of the present disclosure. The operations of the method 1600 may be implemented by a UE or its components as described herein. For example, the operations of the method 1600 may be performed by a UE 115 as described with reference to FIGS. 1 through 10. In some examples, a UE may execute a set of instructions to control the functional elements of the UE to perform the described functions. Additionally, or alternatively, the UE may perform aspects of the described functions using special-purpose hardware.

At 1605, the method may include transmitting an indication of the capability of the UE to decode the message according to one or more puncturing schemes for the spinal coding scheme, where the indication of the puncturing scheme for the spinal coding scheme is based on the capability of the UE. The operations of 1605 may be performed in accordance with examples as disclosed herein. In some examples, aspects of the operations of 1605 may be performed by a UE capability indication component 940 as described with reference to FIG. 9.

At 1610, the method may include receiving, from a network entity, an indication of a puncturing scheme for a spinal coding scheme based on a capability of the UE, where the puncturing scheme indicates a puncturing distribution for one or more symbols of one or more spines of the spinal coding scheme. The operations of 1610 may be performed in accordance with examples as disclosed herein. In some examples, aspects of the operations of 1610 may be performed by a puncturing scheme indication reception component 925 as described with reference to FIG. 9.

At 1615, the method may include receiving, from the network entity, a message encoded according to the spinal coding scheme associated with the puncturing scheme. The operations of 1615 may be performed in accordance with examples as disclosed herein. In some examples, aspects of the operations of 1615 may be performed by an encoded message reception component 930 as described with reference to FIG. 9.

At 1620, the method may include decoding the message encoded according to the spinal coding scheme to obtain one or more message segments corresponding to the one or more symbols and to the one or more spines based on the puncturing distribution of the puncturing scheme. The operations of 1620 may be performed in accordance with examples as disclosed herein. In some examples, aspects of the operations of 1620 may be performed by a decoding component 935 as described with reference to FIG. 9.

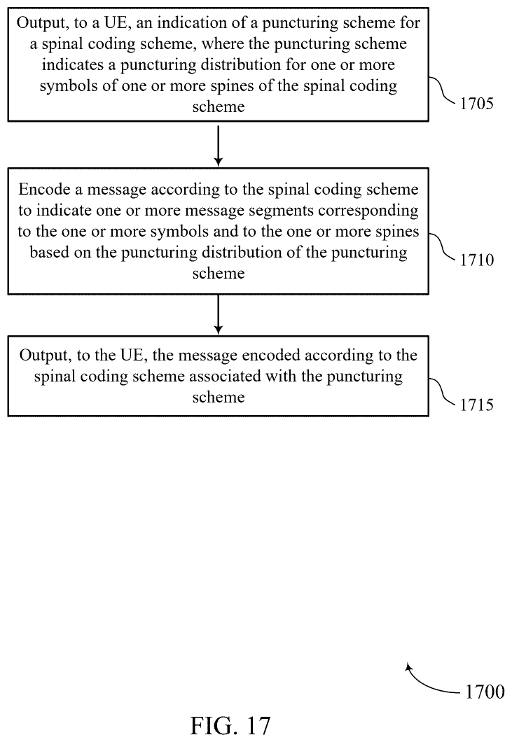

FIG. 17 shows a flowchart illustrating a method 1700 that supports improved puncturing scheme for spinal codes in accordance with one or more aspects of the present disclosure. The operations of the method 1700 may be implemented by a network entity or its components as described herein. For example, the operations of the method 1700 may be performed by a network entity as described with reference to FIGS. 1 through 6 and 11 through 14. In some examples, a network entity may execute a set of instructions to control the functional elements of the network entity to perform the described functions. Additionally, or alternatively, the network entity may perform aspects of the described functions using special-purpose hardware.

At 1705, the method may include outputting, to a UE, an indication of a puncturing scheme for a spinal coding scheme, where the puncturing scheme indicates a puncturing distribution for one or more symbols of one or more spines of the spinal coding scheme. The operations of 1705 may be performed in accordance with examples as disclosed herein. In some examples, aspects of the operations of 1705 may be performed by a puncturing scheme output component 1325 as described with reference to FIG. 13.

At 1710, the method may include encoding a message according to the spinal coding scheme to indicate one or more message segments corresponding to the one or more symbols and to the one or more spines based on the puncturing distribution of the puncturing scheme. The operations of 1710 may be performed in accordance with examples as disclosed herein. In some examples, aspects of the operations of 1710 may be performed by a message encoding component 1330 as described with reference to FIG. 13.

At 1715, the method may include outputting, to the UE, the message encoded according to the spinal coding scheme associated with the puncturing scheme. The operations of 1715 may be performed in accordance with examples as disclosed herein. In some examples, aspects of the operations of 1715 may be performed by an encoded message output component 1335 as described with reference to FIG. 13.

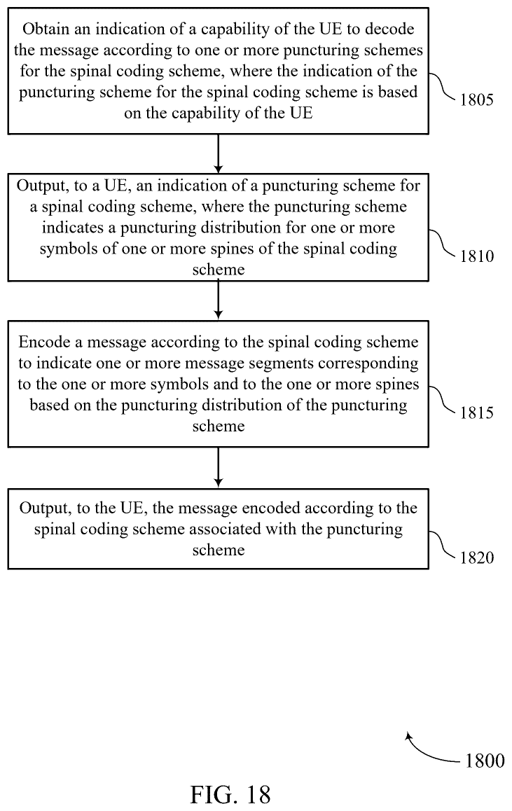

FIG. 18 shows a flowchart illustrating a method 1800 that supports improved puncturing scheme for spinal codes in accordance with one or more aspects of the present disclosure. The operations of the method 1800 may be implemented by a network entity or its components as described herein. For example, the operations of the method 1800 may be performed by a network entity as described with reference to FIGS. 1 through 6 and 11 through 14. In some examples, a network entity may execute a set of instructions to control the functional elements of the network entity to perform the described functions. Additionally, or alternatively, the network entity may perform aspects of the described functions using special-purpose hardware.

At 1805, the method may include obtaining an indication of a capability of the UE to decode the message according to one or more puncturing schemes for the spinal coding scheme, where the indication of the puncturing scheme for the spinal coding scheme is based on the capability of the UE. The operations of 1805 may be performed in accordance with examples as disclosed herein. In some examples, aspects of the operations of 1805 may be performed by a UE capability reception component 1340 as described with reference to FIG. 13.

At 1810, the method may include outputting, to a UE, an indication of a puncturing scheme for a spinal coding scheme, where the puncturing scheme indicates a puncturing distribution for one or more symbols of one or more spines of the spinal coding scheme. The operations of 1810 may be performed in accordance with examples as disclosed herein. In some examples, aspects of the operations of 1810 may be performed by a puncturing scheme output component 1325 as described with reference to FIG. 13.

At 1815, the method may include encoding a message according to the spinal coding scheme to indicate one or more message segments corresponding to the one or more symbols and to the one or more spines based on the puncturing distribution of the puncturing scheme. The operations of 1815 may be performed in accordance with examples as disclosed herein. In some examples, aspects of the operations of 1815 may be performed by a message encoding component 1330 as described with reference to FIG. 13.

At 1820, the method may include outputting, to the UE, the message encoded according to the spinal coding scheme associated with the puncturing scheme. The operations of 1820 may be performed in accordance with examples as disclosed herein. In some examples, aspects of the operations of 1820 may be performed by an encoded message output component 1335 as described with reference to FIG. 13.

The following provides an overview of aspects of the present disclosure:

Aspect 1: A method for wireless communications at a UE, comprising: receiving, from a network entity, an indication of a puncturing scheme for a spinal coding scheme based at least in part on a capability of the UE, wherein the puncturing scheme indicates a puncturing distribution for one or more symbols of one or more spines of the spinal coding scheme; receiving, from the network entity, a message encoded according to the spinal coding scheme associated with the puncturing scheme; and decoding the message encoded according to the spinal coding scheme to obtain one or more message segments corresponding to the one or more symbols and to the one or more spines based at least in part on the puncturing distribution of the puncturing scheme.

Aspect 2: The method of aspect 1, further comprising: transmitting an indication of the capability of the UE to decode the message according to one or more puncturing schemes for the spinal coding scheme, wherein the indication of the puncturing scheme for the spinal coding scheme is based at least in part on the capability of the UE.

Aspect 3: The method of aspect 2, further comprising: receiving, based at least in part on the capability of the UE, an indication of a second puncturing scheme for the spinal coding scheme different from the puncturing scheme; receiving a second message encoded according to the spinal coding scheme in accordance with the second puncturing scheme; and decoding the second message according to the spinal coding scheme based at least in part on a second puncturing distribution of the second puncturing scheme.

Aspect 4: The method of any of aspects 1 through 3, wherein receiving the indication of the puncturing scheme for the spinal coding scheme comprises: receiving one of a radio resource control message or a medium access control (MAC) control element (CE) indicating the puncturing scheme.

Aspect 5: The method of any of aspects 1 through 4, wherein decoding the message comprises: puncturing the one or more symbols of the one or more spines of the spinal coding scheme based at least in part on a uniform puncturing distribution indicated by the puncturing distribution.

Aspect 6: The method of any of aspects 1 through 5, wherein decoding the message comprises: puncturing the one or more symbols of the one or more spines of the spinal coding scheme based at least in part on a puncturing prioritization associated with the puncturing distribution.

Aspect 7: The method of aspect 6, wherein the puncturing prioritization comprises a prioritization of at least one symbol associated with the beginning of the one or more spines.

Aspect 8: The method of any of aspects 1 through 7, wherein the puncturing distribution is based at least in part on an average number of consecutive punctured symbols, an average number of spines of the spinal coding scheme, a growth factor associated with one or more puncturing locations, or a combination thereof.

Aspect 9: A method for wireless communications at a network entity, comprising: outputting, to a UE, an indication of a puncturing scheme for a spinal coding scheme, wherein the puncturing scheme indicates a puncturing distribution for one or more symbols of one or more spines of the spinal coding scheme; encoding a message according to the spinal coding scheme to indicate one or more message segments corresponding to the one or more symbols and to the one or more spines based at least in part on the puncturing distribution of the puncturing scheme; and outputting, to the UE, the message encoded according to the spinal coding scheme associated with the puncturing scheme.

Aspect 10: The method of aspect 9, further comprising: obtaining an indication of a capability of the UE to decode the message according to one or more puncturing schemes for the spinal coding scheme, wherein the indication of the puncturing scheme for the spinal coding scheme is based at least in part on the capability of the UE.

Aspect 11: The method of aspect 10, further comprising: outputting, based at least in part on the capability of the UE, an indication of a second puncturing scheme for the spinal coding scheme different from the puncturing scheme; encoding a second message according to the spinal coding scheme based at least in part on a second puncturing distribution of the second puncturing scheme; and outputting the second message encoded according to the spinal coding scheme in accordance with the second puncturing scheme.

Aspect 12: The method of any of aspects 9 through 11, wherein outputting the indication of the puncturing scheme for the spinal coding scheme comprises: outputting one of a radio resource control message or a medium access control (MAC) control element (CE) indicating the puncturing scheme.

Aspect 13: The method of any of aspects 9 through 12, wherein the puncturing distribution is based at least in part on an average number of consecutive punctured symbols, an average number of spines of the spinal coding scheme, a growth factor associated with one or more puncturing locations, or a combination thereof.

Aspect 14: A UE for wireless communications, comprising one or more memories storing processor-executable code, and one or more processors coupled with the one or more memories and individually or collectively operable to execute the code to cause the UE to perform a method of any of aspects 1 through 8.

Aspect 15: A UE for wireless communications, comprising at least one means for performing a method of any of aspects 1 through 8.

Aspect 16: A non-transitory computer-readable medium storing code for wireless communications, the code comprising instructions executable by one or more processors to perform a method of any of aspects 1 through 8.

Aspect 17: A network entity for wireless communications, comprising one or more memories storing processor-executable code, and one or more processors coupled with the one or more memories and individually or collectively operable to execute the code to cause the network entity to perform a method of any of aspects 9 through 13.

Aspect 18: A network entity for wireless communications, comprising at least one means for performing a method of any of aspects 9 through 13.

Aspect 19: A non-transitory computer-readable medium storing code for wireless communications, the code comprising instructions executable by one or more processors to perform a method of any of aspects 9 through 13.

It should be noted that the methods described herein describe possible implementations. The operations and the steps may be rearranged or otherwise modified and other implementations are possible. Further, aspects from two or more of the methods may be combined.

Although aspects of an LTE, LTE-A, LTE-A Pro, or NR system may be described for purposes of example, and LTE, LTE-A, LTE-A Pro, or NR terminology may be used in much of the description, the techniques described herein are applicable beyond LTE, LTE-A, LTE-A Pro, or NR networks. For example, the described techniques may be applicable to various other wireless communications systems such as Ultra Mobile Broadband (UMB), Institute of Electrical and Electronics Engineers (IEEE) 802.11 (Wi-Fi), IEEE 802.16 (WiMAX), IEEE 802.20, Flash-OFDM, as well as other systems and radio technologies not explicitly mentioned herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed using a general-purpose processor, a DSP, an ASIC, a CPU, a graphics processing unit (GPU), a neural processing unit (NPU), an FPGA or other programmable logic device, discrete gate or transistor logic, discrete hardware components, or any combination thereof designed to perform the functions described herein. A general-purpose processor may be a microprocessor but, in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration). Any functions or operations described herein as being capable of being performed by a processor may be performed by multiple processors that, individually or collectively, are capable of performing the described functions or operations.

The functions described herein may be implemented using hardware, software executed by a processor, firmware, or any combination thereof. If implemented using software executed by a processor, the functions may be stored as or transmitted using one or more instructions or code of a computer-readable medium. Other examples and implementations are within the scope of the disclosure and appended claims. For example, due to the nature of software, functions described herein may be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one location to another. A non-transitory storage medium may be any available medium that may be accessed by a general-purpose or special-purpose computer. By way of example, and not limitation, non-transitory computer-readable media may include RAM, ROM, electrically erasable programmable ROM (EEPROM), flash memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk, and Blu-ray disc. Disks may reproduce data magnetically, and discs may reproduce data optically using lasers. Combinations of the above are also included within the scope of computer-readable media. Any functions or operations described herein as being capable of being performed by a memory may be performed by multiple memories that, individually or collectively, are capable of performing the described functions or operations.

As used herein, including in the claims, “or” as used in a list of items (e.g., a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” and “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

The term “determine” or “determining” encompasses a variety of actions and, therefore, “determining” can include calculating, computing, processing, deriving, investigating, looking up (such as via looking up in a table, a database, or another data structure), ascertaining, and the like. Also, “determining” can include receiving (e.g., receiving information), accessing (e.g., accessing data stored in memory), and the like. Also, “determining” can include resolving, obtaining, selecting, choosing, establishing, and other such similar actions.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label or other subsequent reference label.

The description set forth herein, in connection with the appended drawings, describes example configurations and does not represent all the examples that may be implemented or that are within the scope of the claims. The term “example” used herein means “serving as an example, instance, or illustration” and not “preferred” or “advantageous over other examples.” The detailed description includes specific details for the purpose of providing an understanding of the described techniques. These techniques, however, may be practiced without these specific details. In some figures, known structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A user equipment (UE), comprising:
one or more memories storing processor-executable code; and
one or more processors coupled with the one or more memories and individually or collectively operable to execute the code to cause the UE to:
receive, from a network entity, an indication of a puncturing scheme for a spinal coding scheme based at least in part on a capability of the UE, wherein the puncturing scheme indicates a puncturing distribution for one or more symbols of one or more spines of the spinal coding scheme;
receive, from the network entity, a message encoded according to the spinal coding scheme associated with the puncturing scheme; and
decode the message encoded according to the spinal coding scheme to obtain one or more message segments corresponding to the one or more symbols and to the one or more spines based at least in part on the puncturing distribution of the puncturing scheme.

2. The UE of claim 1, wherein the one or more processors are individually or collectively further operable to execute the code to cause the UE to:
transmit an indication of the capability of the UE to decode the message according to one or more puncturing schemes for the spinal coding scheme, wherein the indication of the puncturing scheme for the spinal coding scheme is based at least in part on the capability of the UE.

3. The UE of claim 2, wherein the one or more processors are individually or collectively further operable to execute the code to cause the UE to:
receive, based at least in part on the capability of the UE, an indication of a second puncturing scheme for the spinal coding scheme different from the puncturing scheme;
receive a second message encoded according to the spinal coding scheme in accordance with the second puncturing scheme; and
decode the second message according to the spinal coding scheme based at least in part on a second puncturing distribution of the second puncturing scheme.

4. The UE of claim 1, wherein, to receive the indication of the puncturing scheme for the spinal coding scheme, the one or more processors are individually or collectively operable to execute the code to cause the UE to:
receive one of a radio resource control message or a medium access control (MAC) control element (CE) indicating the puncturing scheme.

5. The UE of claim 1, wherein, to decode the message, the one or more processors are individually or collectively operable to execute the code to cause the UE to:
puncture the one or more symbols of the one or more spines of the spinal coding scheme based at least in part on a uniform puncturing distribution indicated by the puncturing distribution.

6. The UE of claim 1, wherein, to decode the message, the one or more processors are individually or collectively operable to execute the code to cause the UE to:
puncture the one or more symbols of the one or more spines of the spinal coding scheme based at least in part on a puncturing prioritization associated with the puncturing distribution.

7. The UE of claim 6, wherein the puncturing prioritization comprises a prioritization of at least one symbol associated with a beginning of the one or more spines.

8. The UE of claim 1, wherein the puncturing distribution is based at least in part on an average number of consecutive punctured symbols, an average number of spines of the spinal coding scheme, a growth factor associated with one or more puncturing locations, or a combination thereof.

9. A network entity, comprising:
one or more memories storing processor-executable code; and
one or more processors coupled with the one or more memories and individually or collectively operable to execute the code to cause the network entity to:
output, to a user equipment (UE), an indication of a puncturing scheme for a spinal coding scheme, wherein the puncturing scheme indicates a puncturing distribution for one or more symbols of one or more spines of the spinal coding scheme;
encode a message according to the spinal coding scheme to indicate one or more message segments corresponding to the one or more symbols and to the one or more spines based at least in part on the puncturing distribution of the puncturing scheme; and
output, to the UE, the message encoded according to the spinal coding scheme associated with the puncturing scheme.

10. The network entity of claim 9, wherein the one or more processors are individually or collectively further operable to execute the code to cause the network entity to:
obtain an indication of a capability of the UE to decode the message according to one or more puncturing schemes for the spinal coding scheme, wherein the indication of the puncturing scheme for the spinal coding scheme is based at least in part on the capability of the UE.

11. The network entity of claim 10, wherein the one or more processors are individually or collectively further operable to execute the code to cause the network entity to:
output, based at least in part on the capability of the UE, an indication of a second puncturing scheme for the spinal coding scheme different from the puncturing scheme;
encode a second message according to the spinal coding scheme based at least in part on a second puncturing distribution of the second puncturing scheme; and
output the second message encoded according to the spinal coding scheme in accordance with the second puncturing scheme.

12. The network entity of claim 9, wherein, to output the indication of the puncturing scheme for the spinal coding scheme, the one or more processors are individually or collectively operable to execute the code to cause the network entity to:
output one of a radio resource control message or a medium access control (MAC) control element (CE) indicating the puncturing scheme.

13. The network entity of claim 9, wherein the puncturing distribution is based at least in part on an average number of consecutive punctured symbols, an average number of spines of the spinal coding scheme, a growth factor associated with one or more puncturing locations, or a combination thereof.

14. A method for wireless communications at a user equipment (UE), comprising:
receiving, from a network entity, an indication of a puncturing scheme for a spinal coding scheme based at least in part on a capability of the UE, wherein the puncturing scheme indicates a puncturing distribution for one or more symbols of one or more spines of the spinal coding scheme;
receiving, from the network entity, a message encoded according to the spinal coding scheme associated with the puncturing scheme; and
decoding the message encoded according to the spinal coding scheme to obtain one or more message segments corresponding to the one or more symbols and to the one or more spines based at least in part on the puncturing distribution of the puncturing scheme.

15. The method of claim 14, further comprising:
transmitting an indication of the capability of the UE to decode the message according to one or more puncturing schemes for the spinal coding scheme, wherein the indication of the puncturing scheme for the spinal coding scheme is based at least in part on the capability of the UE.

16. The method of claim 15, further comprising:
receiving, based at least in part on the capability of the UE, an indication of a second puncturing scheme for the spinal coding scheme different from the puncturing scheme;
receiving a second message encoded according to the spinal coding scheme in accordance with the second puncturing scheme; and
decoding the second message according to the spinal coding scheme based at least in part on a second puncturing distribution of the second puncturing scheme.

17. The method of claim 14, wherein receiving the indication of the puncturing scheme for the spinal coding scheme comprises:
receiving one of a radio resource control message or a medium access control (MAC) control element (CE) indicating the puncturing scheme.

18. The method of claim 14, wherein decoding the message comprises:
puncturing the one or more symbols of the one or more spines of the spinal coding scheme based at least in part on a uniform puncturing distribution indicated by the puncturing distribution.

19. The method of claim 14, wherein decoding the message comprises:
puncturing the one or more symbols of the one or more spines of the spinal coding scheme based at least in part on a puncturing prioritization associated with the puncturing distribution.

20. The method of claim 19, wherein the puncturing prioritization comprises a prioritization of at least one symbol associated with a beginning of the one or more spines.

21. The method of claim 14, wherein the puncturing distribution is based at least in part on an average number of consecutive punctured symbols, an average number of spines of the spinal coding scheme, a growth factor associated with one or more puncturing locations, or a combination thereof.

22. A method for wireless communications at a network entity, comprising:
outputting, to a user equipment (UE), an indication of a puncturing scheme for a spinal coding scheme, wherein the puncturing scheme indicates a puncturing distribution for one or more symbols of one or more spines of the spinal coding scheme;
encoding a message according to the spinal coding scheme to indicate one or more message segments corresponding to the one or more symbols and to the one or more spines based at least in part on the puncturing distribution of the puncturing scheme; and
outputting, to the UE, the message encoded according to the spinal coding scheme associated with the puncturing scheme.

23. The method of claim 22, further comprising:
obtaining an indication of a capability of the UE to decode the message according to one or more puncturing schemes for the spinal coding scheme, wherein the indication of the puncturing scheme for the spinal coding scheme is based at least in part on the capability of the UE.

24. The method of claim 23, further comprising:
outputting, based at least in part on the capability of the UE, an indication of a second puncturing scheme for the spinal coding scheme different from the puncturing scheme;
encoding a second message according to the spinal coding scheme based at least in part on a second puncturing distribution of the second puncturing scheme; and
outputting the second message encoded according to the spinal coding scheme in accordance with the second puncturing scheme.

25. The method of claim 22, wherein outputting the indication of the puncturing scheme for the spinal coding scheme comprises:
outputting one of a radio resource control message or a medium access control (MAC) control element (CE) indicating the puncturing scheme.

26. The method of claim 22, wherein the puncturing distribution is based at least in part on an average number of consecutive punctured symbols, an average number of spines of the spinal coding scheme, a growth factor associated with one or more puncturing locations, or a combination thereof.
